(19) United States
(12) Patent Application Publication
(10) Pub. No.: US 2025/0105010 A1
(43) Pub. Date: Mar. 27, 2025

(54) LAYER TRANSFER USING PATTERNED MASKS AND RELATED SYSTEMS

(71) Applicant: Massachusetts Institute of Technology, Cambridge, MA (US)

(72) Inventors: Hyunseok Kim, Cambridge, MA (US); Sangho Lee, Cambridge, MA (US); Jeehwan Kim, Cambridge, MA (US)

(73) Assignee: Massachusetts Institute of Technology, Cambridge, MA (US)

(21) Appl. No.: 18/471,940

(22) Filed: Sep. 21, 2023

(51) Int. Cl. H01L 21/02; C30B 25/04; C30B 29/06; C30B 29/08; C30B 33/00

(52) U.S. Cl. CPC H01L 21/02639; C30B 25/04; C30B 29/06; C30B 29/08; C30B 33/00; H01L 21/02381; H01L 21/0242; H01L 21/02433; H01L 21/02532

(57) ABSTRACT

Methods for growing an epitaxial layer are described herein. In some embodiments, an epitaxial layer is grown over a structure comprising a crystalline substrate and a mask. The mask can be patterned with a plurality of elongated domains that help may facilitate the growth of the epitaxial layer with a reduced number of defects on the crystalline substrate. The mask may also facilitate the separation of the epitaxial layer from the crystalline substrate to form a separated epitaxial layer that is freestanding. In some embodiments, the method for growing an epitaxial layer may allow for heteroepitaxy of compound semiconductors on elemental substrates with a reduced number of defects despite polarity and/or lattice mismatches.

### GOVERNMENT SPONSORSHIP

This invention was made with government support under D19AP00037 awarded by the Defense Advanced Research Projects Agency. The government has certain rights in the invention.

### TECHNICAL FIELD

Layer transfer using patterned masks and related systems are generally described.

### SUMMARY

The present disclosure is related to layer transfer using patterned masks and related systems. Certain of the methods in this disclosure comprise growing epitaxial layers over masks patterned with respect to crystallographic directions on a crystalline substrate in a manner that improves the quality of epitaxial layer (e.g., by reducing defects). The subject matter of the present disclosure involves, in some cases, interrelated products, alternative solutions to a particular problem, and/or a plurality of different uses of one or more systems and/or articles.

In one aspect, methods of growing an epitaxial layer are provided. In some embodiments, the method comprises growing an epitaxial layer over a structure comprising a crystalline substrate and a mask such that the mask is between the epitaxial layer and the crystalline substrate; and separating the epitaxial layer and the crystalline substrate from each other; wherein: the crystalline substrate has a diamond cubic crystal structure or a zinc blende crystal structure; the mask and the epitaxial layer are over a {100} plane of the crystalline substrate; the mask comprises a plurality of elongated domains, each elongated domain having long edges; each of the long edges is within 10 degrees of parallel to a <110> direction on the {100} plane of the crystalline substrate, on a {100} plane of the epitaxial layer, or both.

In certain embodiments, the method comprises growing an epitaxial layer over a structure comprising a crystalline substrate and a mask comprising a plurality of elongated domains, each elongated domain having long edges, such that elongated domains are between the epitaxial layer and the crystalline substrate; and separating the epitaxial layer and the crystalline substrate from each other; wherein: the elongated domains of the mask are not connected to each other; and the elongated domains occupy at least 50% of a facial surface area of the crystalline substrate.

Other advantages and novel features of the present disclosure will become apparent from the following detailed description of various non-limiting embodiments of the disclosure when considered in conjunction with the accompanying figures. In cases where the present specification and a document incorporated by reference include conflicting and/or inconsistent disclosure, the present specification shall control.

### BRIEF DESCRIPTION OF THE DRAWINGS

Non-limiting embodiments of the present disclosure will be described by way of example with reference to the accompanying figures, which are schematic and are not intended to be drawn to scale unless otherwise indicated. In the figures, each identical or nearly identical component illustrated is typically represented by a single numeral. For purposes of clarity, not every component is labeled in every figure, nor is every component of each embodiment of the disclosure shown where illustration is not necessary to allow those of ordinary skill in the art to understand the disclosure. In the figures:

FIG. 1A is a top-view schematic diagram of a crystalline substrate, according to some embodiments.

FIG. 1B is a cross-sectional schematic diagram of the crystalline substrate of FIG. 1A, with the cross-section taken along the dashed line of FIG. 1A, in accordance with certain embodiments.

FIG. 1C is a top-view schematic diagram of a structure comprising the crystalline substrate of FIGS. 1A-1B and a mask, according to some embodiments.

FIG. 1D is a cross-sectional schematic diagram of the structure of FIG. 1C, with the cross-section taken along the dashed line of FIG. 1C, according to certain embodiments.

FIG. 1E is a cross-sectional schematic diagram of an epitaxial layer over the structure comprising the crystalline substrate and the mask of FIGS. 1C-1D, according to some embodiments.

FIG. 2A is a cross-sectional schematic diagram of the epitaxial layer, the structure of FIGS. 1C-1D, and a stressor layer prior to separation, according to some embodiments.

FIG. 2B is a cross-sectional schematic diagram showing the separation of the epitaxial layer, according to some embodiments.

FIG. 3A is a series of perspective-view schematic illustrations of epitaxy on nanopatterned graphene and layer release, according to some embodiments.

FIG. 3B is a series of plan-view SEM images (left) and EBSD maps (right) of GaAs and Ge grown on GaAs and Ge substrates, showing planarized single-crystalline thin films, according to some embodiments. Scale bars, 2 μm.

FIG. 3C shows three modes of peeling as a function of the stressor thickness and epilayer thickness at a Ni stress level of 600 MPa and graphene coverage of 70% on a Ge substrate, according to some embodiments. The dashed line represents natural spalling depth without graphene.

FIG. 3D show the effect of graphene coverage on the peeling modes at a stressor stress of 600 MPa and epilayer thickness of 1 m, according to some embodiments.

FIG. 3E shows plan-view SEM images of the substrate after the peeling, according to some embodiments.

FIG. 3F shows atomic force microscopy (AFM) images of the substrate after the peeling, according to some embodiments.

FIG. 3G shows a plan-view SEM image of GaAs substrate in the spalling regime, according to some embodiments.

FIG. 3H shows plan-view SEM images of sample surfaces in delamination regime, showing delamination at the Ni/epilayer interface (left) and tape/Ni interface (right), according to some embodiments.

FIG. 4A shows cross-sectional scanning transmission electron microscopy (STEM) images of GaAs grown directly on Ge, according to some embodiments.

FIG. 4B shows cross-sectional scanning transmission electron microscopy (STEM) images of GaAs grown directly on nanopatterned graphene-coated Ge, according to some embodiments.

FIG. 4C shows plan-view SEM images of AlGaAs red LEDs grown on bare Ge, according to some embodiments.

FIG. 4D shows plan-view SEM images of AlGaAs red LEDs grown and on nanopatterned graphene-coated Ge, according to some embodiments.

FIG. 4E shows a cross-sectional SEM image of an LED fabricated by exfoliating the LED structure from the substrate and transferring onto polyimide/silicon substrate, according to some embodiments.

FIG. 4F shows microscopic photographs of EL from red LEDs with different sizes and geometries on nanopatterned graphene-coated Ge, according to some embodiments.

FIG. 4G shows microscopic photographs of EL from red LEDs with different sizes and geometries on bare Ge, according to some embodiments.

FIG. 4H shows I-V curves of fabricated LEDs on Ge with and without nanopatterned graphene, according to some embodiments.

FIG. 5A shows a low-magnification STEM image of InAs grown directly on InP without a mask, according to some embodiments.

FIG. 5B shows a high-resolution STEM image (left) and corresponding GPA maps showing in-plane (center) and out-of-plane (right) strain, according to some embodiments.

FIG. 5C shows a low-magnification STEM image of InAs grown on a graphene pattern, according to some embodiments.

FIG. 5D shows a high-resolution STEM image and corresponding GPA maps at the edge of graphene, showing relaxed InAs film with slightly deformed graphene, according to some embodiments.

FIG. 5E shows a low-magnification STEM image for InAs grown on SiO₂ pattern, according to some embodiments.

FIG. 5F shows a high-resolution STEM image and corresponding GPA maps at the edge of graphene, showing severe strain at the interface and at the mask edge, according to some embodiments.

FIG. 6A shows electron channeling contrast imaging (ECCI) images of InAs grown on nanopatterned graphene-coated GaAs with different graphene coverages, according to some embodiments. Scale bars are 200 nm.

FIG. 6B shows the surface dislocation density as a function of graphene coverage measured by ECCI, according to some embodiments.

FIG. 7 shows calculated stress intensity factors, K_{I} (grey) and K_{II} (red), for a 4 μm Ni stressor layer with 600 Mpa tensile stress on a Ge(100) substrate, according to embodiments.

FIG. 8A shows plan-view SEM images of nominally 1 μm-thick Ge grown on nanopatterned graphene-coated Ge substrates with the pattern period of 300 nm, according to some embodiments.

FIG. 8B shows plan-view SEM images of nominally 1 μm-thick Ge grown on nanopatterned graphene-coated Ge substrates with the pattern period of 600 nm, according to some embodiments.

FIG. 9A shows plan-view SEM images (left) and EBSD maps (right) of InAs grown on nanopatterned graphene-coated InAs, according to some embodiments.

FIG. 9B shows plan-view SEM images (left) and EBSD maps (right) of InP grown on nanopatterned graphene-coated InP, according to some embodiments.

FIG. 9C shows plan-view SEM images of the InAs substrate after exfoliation of grown films, according to some embodiments.

FIG. 9D shows plan-view SEM images of the InP substrate after exfoliation of grown films, according to some embodiments.

FIG. 10A shows X-ray diffraction rocking curves of 1-μm-thick GaAs grown on a nanopatterned graphene/Ge substrate with the pattern periodicity of 1200 nm and the opening width of about 480 nm, according to some embodiments.

FIG. 10B shows X-ray diffraction rocking curves of 1-μm-thick GaAs grown on a bare Ge substrate with the pattern periodicity of 1200 nm and the opening width of about 480 nm, according to some embodiments.

FIG. 11A shows peeling modes of a Ge epilayer on Ge(100) with a graphene coverage of 70%, as a function of the epilayer thickness and Ni thickness under the Ni stress level of 1200 Mpa which can be obtained by electroplating of Ni, according to some embodiments.

FIG. 11B shows peeling modes of a 1-μm-thick Ge epilayer on Ge(100) under a Ni stress level of 1200 Mpa, as a function of the graphene coverage and Ni thickness, according to some embodiments.

FIG. 12A shows plan-view SEM images of nominally 1 μm-thick GaAs grown on nanopatterned graphene-coated on-axis Ge(100) substrates. APB is eliminated when graphene stripes are patterned along <110> directions, according to some embodiments.

FIG. 12B shows plan-view SEM images of nominally 1 μm-thick GaAs grown on nanopatterned graphene-coated on-axis Ge(100) substrates. APBs are observed when graphene stripes are patterned along <100> directions.

FIG. 13A shows peeling modes of a GaAs epilayer on GaAs(100) with a graphene coverage of 70%, as a function of the epilayer thickness and Ni thickness under the stress level of 600 Mpa, according to some embodiments.

FIG. 13B shows peeling modes of an InAs epilayer on InAs(100) with a graphene coverage of 70%, as a function of the epilayer thickness and Ni thickness under the stress level of 600 Mpa, according to some embodiments.

FIG. 13C shows peeling modes of an InP epilayer on InP(100) with a graphene coverage of 70%, as a function of the epilayer thickness and Ni thickness under the stress level of 600 Mpa, according to some embodiments

FIG. 13D shows peeling modes of a 1 μm-thick GaAs epilayer on GaAs(100) under a Ni stress level of 600 Mpa, as a function of the graphene coverage and Ni thickness, according to some embodiments.

FIG. 13E shows peeling modes of a 1 μm-thick InAs epilayer on InAs(100) under a Ni stress level of 600 Mpa, as a function of the graphene coverage and Ni thickness, according to some embodiments.

FIG. 13F shows peeling modes of a 1 μm-thick InP epilayer on InP(100) under a Ni stress level of 600 Mpa, as a function of the graphene coverage and Ni thickness, according to some embodiments.

### DETAILED DESCRIPTION

Methods for growing epitaxial layers (also sometimes referred to as “epilayers”) are described herein. In some embodiments, an epitaxial layer is grown over a structure comprising a crystalline substrate and a mask. The mask can be patterned with a plurality of elongated domains that are parallel or close to parallel (e.g., within 10 degrees of parallel, or closer to parallel) to a direction of the <110> family of directions on a plane of the {100} family of planes on the crystalline substrate. The plurality of elongated domains may facilitate the growth of the epitaxial layer with a reduced number of defects on the crystalline substrate. The mask may also facilitate the separation of the epitaxial layer from the crystalline substrate. This can allow for the formation of freestanding epitaxial layers. In some embodiments, the method for growing an epitaxial layer may allow for heteroepitaxy of compound semiconductors on elemental substrates with a reduced number of defects despite polarity and/or lattice mismatches.

With the advancement of current electronic and photonic devices, demands for heterogeneous integration of dissimilar materials are continuously increasing to realize multifunctional chips on a single platform. Heterointegration of single-crystalline materials has traditionally been carried out either by monolithic approaches using heteroepitaxy or by transfer of semiconductor membranes from foreign substrates. For heteroepitaxy, elemental semiconductors such as Si and Ge have been utilized as epitaxial templates for growing compound semiconductors owing to their substantially lower costs and compatibility with mature platforms. However, heteroepitaxy has historically not avoided the formation of crystalline defects such as dislocations and antiphase boundaries (APBs), which severely deteriorate device performance. Anti-phase boundaries generally form due to defects and/or step-edges on surfaces of the crystalline substrate and are difficult to eliminate during wafer and/or crystalline substrate production.

Certain aspects of the present disclosure involve methods to reduce crystallographic defects in heteroepitaxial layers while allowing relatively fast mechanical layer release. In accordance with certain embodiments, this can be realized by performing epitaxy over a substrate over which a patterned mask (e.g., a nanopatterned mask) is positioned. The epitaxial growth can involve initial formation of the epilayer on exposed portions of the substrate followed by lateral overgrowth. Certain embodiments described herein can provide one or more of the following advantages: i) epilayers and wafters can be readily separated from each other by simple mechanical exfoliation (e.g., due to reduced interface toughness with the nanopatterned mask), ii) elemental materials can be used not only as substrates but can be made as freestanding membranes, iii) the materials (e.g., compound semiconductors and/or other crystalline materials) can be fabricated with a reduced number of APBs, even on elemental semiconductor substrates, and iv) dislocations can be reduced in lattice-mismatched heteroepitaxial systems due to lateral relaxation and/or by the flexibility and chemical inertness of the mask material (e.g., graphene).

Certain aspects are directed to methods of growing an epitaxial layer. In some embodiments, the method of growing an epitaxial layer comprises growing an epitaxial layer over a structure. The structure comprises, in accordance with certain embodiments, a crystalline substrate and a mask. The mask, in certain embodiments, can be between the epitaxial layer and the crystalline substrate. The mask may comprise a plurality of elongated domains wherein each elongated domain has long edges (e.g., two edges that are parallel or substantially parallel to each other, such as when the elongated domain is in the form of a stripe). The long edges of the plurality of elongated domains can, in some embodiments, be within 10 degrees of parallel to a direction in the <110> family of directions on a plane in the {100} family of planes on the crystalline substrate. In some embodiments, the method of growing the epitaxial layer further comprises separating the epitaxial layer and the crystalline substrate from each other. This separation can result in the formation of a first structure that comprises a substrate and a second structure that comprises the epitaxial layer.

Advantageously, in accordance with certain embodiments, the epitaxial layers produced using the systems and methods described herein can comprise relatively low defect densities and/or anti-phase domain (APD) densities. Accordingly, electronic devices (e.g., diodes, transistors, rectifiers, etc.) comprising the epitaxial layers can, in some embodiments, exhibit improved performance. For example, in some embodiments, a light-emitting diode comprising the separated epitaxial layer may exhibit higher electroluminescence and/or lower forward bias recombination current than a light-emitting diode not comprising the separated epitaxial under otherwise identical conditions.

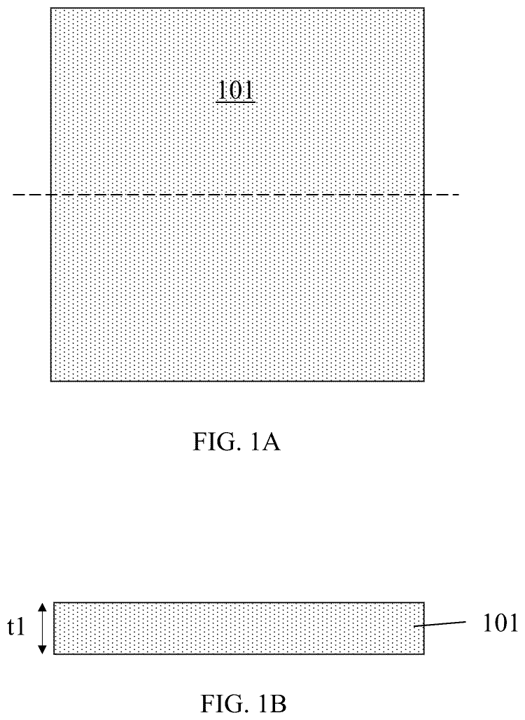

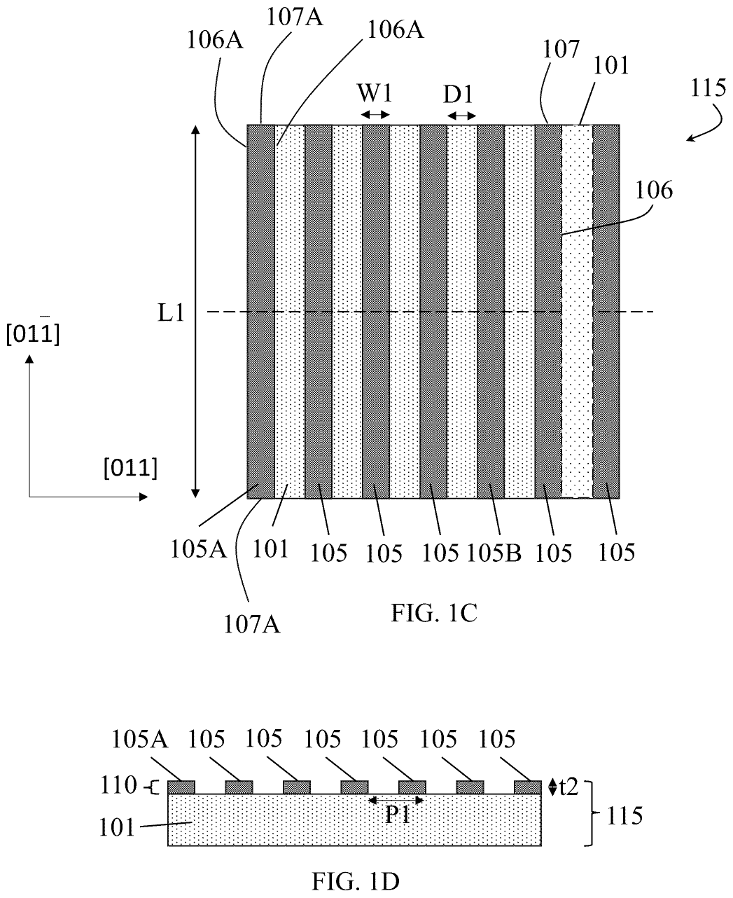

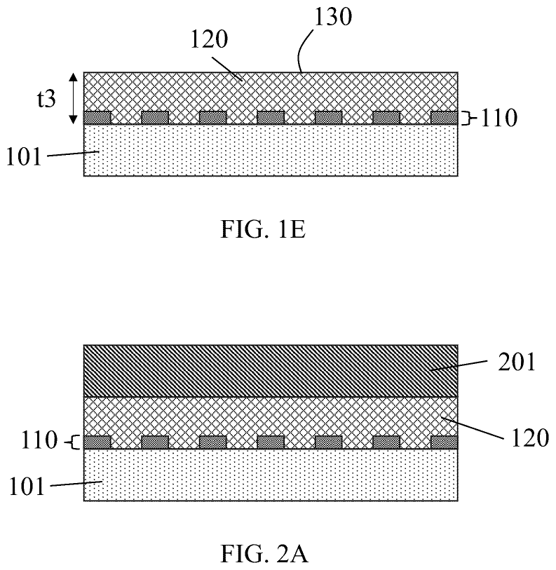

The epitaxial layer can be formed, in some embodiments, over a substrate. One example of such a substrate is shown in FIGS. 1A-1B. In FIGS. 1A-1B, crystalline substrate 101 is shown from a top view (FIG. 1A) and a cross-sectional view (FIG. 1B), and substrate 101 has thickness t1.

A variety of types of substrates can be employed. In some embodiments, the crystalline substrate comprises silicon, germanium, carbon (e.g., diamond), α-tin, and/or compound semiconductors including but not limited to gallium arsenide (GaAs), gallium phosphide (GaP), indium phosphide (InP), indium arsenide (InAs), indium antimonide (InSb), aluminum phosphide (AlP), aluminum arsenide (AlAs), aluminum antimonide (AlSb), zinc selenide (ZnSe), cadmium sulfide (CdS), III-V semiconductors, I-VII semiconductors, and/or II-VI semiconductors. In some embodiments, the substrate comprises a III-nitride material, such as a gallium nitride material or an aluminum nitride material. In some embodiments, the substrate comprises a III-phosphide material. In some embodiments, the substrate comprises a III-arsenide material. In some embodiments, the substrate is an elemental substrate.

In some embodiments, the crystalline substrate comprises at least one crystalline domain. In some embodiments, the at least one crystalline domain comprises a diamond cubic crystal structure or a zinc blende crystal structure. In some embodiments, the crystalline substrate is a single crystal (e.g., a single crystalline substrate comprising a diamond cubic crystal structure or a zinc blende crystal structure). For example, in some embodiments, the substrate is a single crystal wafter (e.g., single crystal semiconductor wafer or other single crystal wafer).

In some embodiments, a surface of the crystalline substrate on which epitaxy is performed to form the epitaxial layer is not monoatomically smooth. For example, in certain embodiments, the surface of the crystalline substrate on which epitaxy is performed may comprise defects including but not limited to monoatomic steps and/or terraces. Traditionally, epitaxy (homoepitaxial or heteroepitaxy) on the surface of the crystalline substrate that is not monoatomically smooth can result in epitaxial layers comprising crystalline defects including but not limited to edge dislocations, screw dislocations, and/or anti-phase boundaries (APBs). Such defects can negatively impact the performance of electronic devices fabricated from the epitaxial formations. Certain embodiments involve the use of systems and methods under which such defects are reduced or even eliminated, even when the surface of the crystalline substrate on which epitaxy is performed is not monoatomically smooth. Of course, the embodiments described herein are not limited to such examples, and in some cases, the surface of the crystalline substrate on which epitaxy is performed is monoatomically smooth.

In some embodiments, the crystalline substrate has no polarity. For example, the crystalline substrate can be, in some embodiments, a IV substrate such as silicon or germanium substrates. In some embodiments, the crystalline substrate can have a polarity. For example, in some embodiments, the crystalline substrate is a III-V substrate. In some embodiments, the crystalline substrate has a different polarity than that of the epitaxial layer that is grown on the substrate. Polarity mismatches between the crystalline substrate and the epitaxial layer have, traditionally, led to the formation of anti-phase boundaries within the epitaxial layer. As mentioned above, such defects generally negatively impact the performance of electronic devices fabricated from the epitaxial layer with anti-phase boundaries. Certain embodiments involve the use of systems and methods under which such anti-phase boundaries are reduced or even eliminated.

In certain embodiments, the epitaxial layer is grown over a structure comprising the crystalline substrate and a mask. One example of such a structure is structure 115 in FIGS. 1C-1D. In FIG. 1C-1D, a top view (FIG. 1C) and cross-sectional view (FIG. 1D) of structure 115 comprising mask 110 and crystalline substrate 101 is shown. As shown in FIGS. 1C-1D, mask 110 has thickness t2.

In some embodiments, the mask comprises plurality of elongated domains. The elongated domains can be made of a solid material that covers a portion of the substrate and is positioned between the substrate and the epitaxial layer during and after growth of the epitaxial layer. For example, referring to FIG. 1C, mask 110 comprises a plurality of elongated domains 105, which are in the form of stripes. As explained in more detail elsewhere herein, aligning the long edges of the elongated domains along <110> directions of a {100} plane of the growth substrate and growing the epitaxial layer over that {100} plane of the growth substrate can lead to the reduction or elimination of antiphase boundaries within the epitaxial layer.

In some embodiments, the mask is between the epitaxial layer and the crystalline substrate. For example, in FIG. 1E, mask 110 is between crystalline substrate 101 and epitaxial layer 120. In some embodiments, the mask can be in direct contact with the epitaxial layer and the crystalline substrate as it can be sandwiched between the epitaxial layer and the crystalline substrate. The mask may help facilitate quick and damage-free release of the epitaxial layer from the crystalline substrate due to the weak van der Waals interactions between the mask and the epitaxial layer. In some embodiments, the mask may have direct contact with the crystalline substrate and the epitaxial layer. The openings within the mask can allow for direct epitaxial seeding of the epitaxial layer on the crystalline substrate.

In some embodiments, the mask material has a relatively low thickness. For example, in FIG. 1D, thickness t1 of mask 110 can be relatively small. In some embodiments, the mask has a thickness of less than or equal to 10 micrometers, less than or equal to 5 micrometers, less than or equal to 1 micrometer, less than or equal to 500 nanometers, less than or equal to 200 nanometers, less than or equal to 100 nanometers, less than or equal to 50 nanometers, less than or equal to 10 nanometers, less than or equal to 5 nanometers, or less than or equal to 2 nanometers. In some embodiments, the mask has a thickness of greater than or equal to 0.1 nanometers, greater than or equal to 0.25 nanometers, greater than or equal to 0.5 nanometers, greater than or equal to 1 nanometer, greater than or equal to 5 nanometers, greater than or equal to 10 nanometers, greater than or equal to 50 nanometers, or greater than or equal to 100 nanometers. Combinations of these ranges are also possible (e.g., greater than or equal to 0.1 nanometers and less than or equal to 10 micrometers).

In some embodiments, the mask comprises a monolayer of atoms. In some embodiments, the mask comprises a bilayer of atoms). In some embodiments, the mask can be arranged as a plurality of atomic layers (e.g., at least 2, 3, 4, 5, 6, 7, or more atomic layers). For example, in some embodiments, a plurality of graphene layers (e.g., 2, 3, 4, 5, 6, 7, or more graphene layers thick) can be used. In some embodiments, the mask is an atomically thin material.

In some embodiments, the mask comprises a two-dimensional (2D) material. 2D materials are those that are arranged as a single layer of atoms and, accordingly, are a single atom in thickness. The 2D material can include any of a variety of 2D materials. In some embodiments, the 2D material can include graphene (single crystalline or polycrystalline). In some cases, the 2D material comprises a transition metal dichalcogenide (TMD) monolayer (e.g., MoS₂ and/or Wse₂) which is an atomically thin semiconductor of the type MX₂, where M is a transition metal atom (e.g., Mo, W, etc.) and X is a chalcogen atom (e.g., S, Se, or Te). The 2D layer, in certain embodiments, comprises 2D boron nitride. In certain embodiments a single layer of mask material is present (e.g., a single layer of 2D material may be used as a mask). In other embodiments, multiple layers of material (e.g., multiple layers of 2D material) may be used as a mask.

In some embodiments, the mask comprises a dielectric mask. Examples of dielectric masks include but are not limited to silicon dioxide, silicon carbide, silicon nitride, silicon oxynitride, aluminum oxide, hafnium oxide, tungsten oxide, and other hard mask materials. In some embodiments, the mask comprises tungsten.

In some embodiments, the mask occupies a relatively high portion of the facial surface area of the crystalline substrate over which the epitaxial layer is grown. The facial surface area of the crystalline substrate over which the epitaxial layer is grown, in certain embodiments, is a plane of the {100} family of planes of the crystalline substrate. The facial surface area of the crystalline substrate that the mask occupies may influence the quality and ease of separation of the separated epitaxial layer. In some embodiments, the mask occupies at least 90%, at least 95%, at least 98%, at least 99%, at least 99.9%, or at least 99.99% of the facial surface area of the crystalline substrate over which the epitaxial layer is grown. In this context, the facial surface area of the crystalline substrate that the mask occupies is calculated by dividing the facial surface area occupied by the outer boundaries of the mask (which includes both the areas that are covered by mask material and areas that are uncovered by mask material but which are, nonetheless, within the outer boundaries of the mask material) by the facial surface area of the substrate over which the epitaxial layer is grown and multiplying the result by 100%. For example, in FIG. 1C and FIG. 1D, mask 110 occupies the entire facial surface area of the substrate because the outer boundaries of mask 110 and the outer boundaries of substrate 101, when viewed from above, are coextensive.

In some embodiments, the plurality of elongated domains occupies a relatively large percentage of the facial surface area of the crystalline substrate over which the epitaxial layer is grown. In certain embodiments, the plurality of elongated domains occupies at least 20%, at least 35%, at least 50%, at least 60%, at least 75%, at least 85%, at least 90%, or at least 95% of the facial surface area of the crystalline substrate over which the epitaxial layer is grown. In certain embodiments, the plurality of elongated domains occupies less than or equal to 99% or less than or equal to 98% of the facial surface area of the crystalline substrate over which the epitaxial layer is grown. Combinations of these ranges are also possible (e.g., at least 20% and less than or equal to 99%). In this context, the facial surface area of the crystalline substrate that the elongated domains occupy is calculated by dividing the facial surface area of the elongated domains (which includes only the areas that are occupied by the elongated domains and does not include the areas of the substrate that are uncovered by mask material but which are within the outer boundaries of the mask material) by the facial surface area of the substrate over which the epitaxial layer is grown and multiplying the result by 100%. For example, in FIG. 1C and FIG. 1D, the facial surface area of crystalline substrate 101 that elongated domains 105 occupy is around 50%, since around 50% of the facial surface area of substrate 101 is covered by elongated domains 105.

In some embodiments, the mask can be grown and/or deposited over the crystalline substrate. The mask may be grown over the crystalline substrate via chemical vapor deposition (CVD). In some embodiments, the mask can be grown on a second substrate (e.g., copper foil) and can be transferred over to the crystalline substrate. In some embodiments, the mask can be annealed after deposition over the crystalline substrate.

In some embodiments, the mask comprises a pattern. In some embodiments, the mask can be patterned via any of a variety of lithography techniques. The mask, in certain embodiments, can be patterned via electron-beam lithography, interference lithography, stepper lithography, and/or other lithographic techniques known in the art.

In some embodiments, the mask can be over a plane in the {100} family of planes of the crystalline substrate. The {100} family of planes, denoted with braces used in accordance with the Miller index notation for crystallographic planes and directions, indicates the (100) plane as well as other planes of the same plane family. That is to say, the {100} family of planes is the following set of planes: the (100) plane, the (1̅00) plane, the (01̅0) plane, the (010) plane, the (001) plane, and the (001̅) plane.

As noted above, in some embodiments, the mask comprises a plurality of elongated domains. The elongated domains can be made of a material that covers a portion of the substrate and is positioned between the substrate and the epitaxial layer during and after growth of the epitaxial layer.

In some embodiments, each of the plurality of elongated domains comprises long edges and short edges. For example, in FIG. 1C, elongated domain 105A comprises long edges 106A (which run along the length, L1, of elongated domain 105A) and short edges 107A (which run along the width of elongated domain 105A). Other elongated domains 105 in FIG. 1C also comprise long edges 106 and short edges 107. The long edge cans, in some embodiments, be parallel to or substantially parallel to a direction in the <110> family of directions on a plane in the {100} family of planes of the crystalline substrate, the epitaxial layer, or both.

The <110> family of directions, denoted with angle brackets in accordance with the Miller index notation for crystallographic planes and directions, includes the [110] direction as well as other directions in the same family of directions. That is to say, the <110> family of directions is the following set of directions: the [110] direction, the [110] direction, the [110] direction, the [110] direction, the [101] direction, the [101] direction, the [101] direction, the [101] direction, the [011] direction, the [011] direction, the [011] direction, and the [011] direction.

In some embodiments, the long edges of the elongated domains are within 10 degrees of parallel to a direction in the <110> family of directions on a plane in the {100} family of planes on the crystalline substrate, the epitaxial layer, or both. In some embodiments, the long edges of the elongated domains are within 10 degrees, within 5 degrees, within 2 degrees, within 1 degree, or within 0.5 degrees of parallel to a direction in the <110> family of directions on a plane in the {100} family of planes on the crystalline substrate. One example of this is shown in FIG. 1C, in which elongated domains 105 are formed over the (100) plane of substrate 101. In FIG. 1C, the long edges 106 of elongated domains 105 are parallel to the [011] direction (and, thus, are within 10 degrees, within 5 degrees, within 2 degrees, within 1 degrees, and within 0.5 degrees of parallel to a direction in the <110> family of directions). In some embodiments, the long edges of the elongated domains are within 10 degrees, within 5 degrees, within 2 degrees, within 1 degree, or within 0.5 degrees of parallel to a direction in the <110> family of directions on a plane in the {100} family of planes on the epitaxial layer. In some embodiments, the long edges of the elongated domains are within 10 degrees, within 5 degrees, within 2 degrees, within 1 degree, or within 0.5 degrees of parallel to a direction in the <110> family of directions on a plane in the {100} family of planes on both the crystalline substrate and the epitaxial layer.

In some embodiments, the mask comprises a plurality of elongated domains that are not connected to each other via the same material from which the elongated domains are made. That is to say, the elongated domains within the mask can be discontinuous. For example, in FIG. 1C and FIG. 1D, mask 110 comprises elongated domains 105 are not connected and/or coupled together by the material from which the elongated domains are made. In FIGS. 1C and 1D, each one of the elongated domains is not in direct contact with another elongated domain and is therefore discontinuous. The embodiments described herein are not necessarily limited to using masks have discontinuous elongated domains, and in other embodiments, the elongated domains can be part of a layer of mask material in which the elongated domains are connected to each other. For example, in some embodiments, the mask material (e.g., graphene, 2D materials, or other mask materials) can be patterned such that elongated domains of the mask material are formed by patterning trenches between elongated domains of the mask material while the elongated domains of the mask material remain connected via portions of mask material at the top and/or bottom of the mask.

In some embodiments, the long edges of the elongated domains are parallel to or substantially parallel to one, more, or all of the long edges of the other elongated domains of the mask material. For example, in some embodiments, the long edges of the elongated domains are within 10 degrees, within 5 degrees, within 2 degrees, within 1 degree, or within 0.5 degrees of parallel to at least 2, at least 4, at least 6, or more (e.g., all) of the long edges of other elongated domains within the mask. In FIG. 1C, for example, long edges 106A of elongated domain 105A are parallel to all of the other long edges of elongated domains 105 within mask 110.

The elongated domains can have any of a variety of aspect ratios. In this context, the aspect ratio is the ratio of the length of the elongated domain to the width of the elongated domain. For example, in FIG. 1C, elongated domains 105 each have width W1 and length L1. In some embodiments, each of the plurality of elongated domains each have an aspect ratio of at least 10:1. In some embodiments, each of the plurality of elongated domains have an aspect ratio of at least 10:1, at least 50:1, at least 100:1, at least 1000:1, at least 10,000:1, at least 100,000:1, at least 1,000,000:1, at least 10,000,000, or more.

The elongated domains can have any of a variety of widths. In some embodiments, each of the plurality of elongated domains has a width that is greater than or equal to 25 nm, greater than or equal to 50 nm, greater than or equal to 100 nm, greater than or equal to 250 nm, greater than or equal to 500 nm, greater than or equal to 1000 nm, greater than or equal to 5 micrometers, or greater than or equal to 10 micrometers. In some embodiments, each of the plurality of elongated domains have a width that is less than or equal to 10 micrometers, less than or equal to 5 micrometers, less than or equal to 1000 nm, less than or equal to 500 nm, less than or equal to 250 nm, less than or equal to 100 nm, less than or equal to 50 nm, or less than or equal to 25 nm. Combinations of these ranges are also possible (e.g., greater than or equal to 25 nm and less than or equal to 10 micrometers).

In some embodiments, the plurality of elongated domains is arranged in a periodic pattern. The average frequency, or average pitch, of the periodic pattern may, in certain embodiments, reduce the formation of anti-phase boundaries in the epitaxial layer and/or facilitate separation of the epitaxial layer from the substrate and/or other parts of the structure. For example, in FIG. 1D, mask 110 comprises a periodic pattern with pitch P1. In some embodiments, the pitch of the periodic pattern can be greater than or equal to 100 nm, greater than or equal to 250 nm, greater than or equal to 500 nm, greater than or equal to 750, greater than or equal to 1000 nm, or greater than or equal to 2000 nm. In some embodiments, the pitch of the periodic pattern can be less than or equal to 2000 nm, less than or equal to 1000 nm, less than or equal to 750 nm, less than or equal to 500 nm, less than or equal to 250 nm, or less than or equal to 100 nm. Combinations of these ranges are also possible (e.g., greater than or equal to 100 nm and less than or equal to 2000 nm).

In some embodiments, each of the plurality of elongated domains has a nearest neighbor (i.e., another of the elongated domains that is closest to the elongated domain being analyzed). It is possible that an elongated domain can have two nearest neighbors, one on either side of the elongated domain. In FIG. 1C, distance D1 separates each of elongated domains 105 from the nearest neighbor(s). In addition, in FIG. 1C, elongated domain 105A has one nearest neighbor (to the right of elongated domain 105A in FIG. 1C), while elongated domain 105B has two nearest neighbors (one on either side of it). The distance between the nearest neighbor(s) of each of the plurality of elongated domains may affect the rate and/or defect density of the epitaxial layer. In some embodiments, the average nearest neighbor distance among the plurality of elongated domains is less than or equal to 10 micrometers, less than or equal to 5 micrometers, less than or equal to 1 micrometer, less than or equal to 750 nm, less than or equal to 500 nm, less than or equal to 250 nm, less than or equal to 100 nm, or less than or equal to 50 nm. In some embodiments, the average nearest neighbor distance among the plurality of elongated domains is greater than or equal to 50 nm, greater than or equal to 100 nm, greater than or equal to 250 nm, greater than or equal to 500 nm, greater than or equal to 750 nm, greater than or equal to 1 micrometer, greater than or equal to 5 micrometers, or greater than or equal to 10 micrometers. Combinations of these ranges are also possible (e.g., less than or equal to 10 micrometers and greater than or equal to 50 nm). The average nearest neighbor distance among a plurality of elongated domains is calculated by determining the nearest neighbor distance for each of the elongated domains and then calculating the numerical average of those distances. (In cases where an elongated domain includes two nearest neighbors, only one of those nearest neighbor distances is used to calculate the average nearest neighbor distance among the plurality of elongated domains.) The average nearest neighbor distance among the plurality of elongated domains can also be referred to as the pattern pitch.

In some embodiments, the mask has a relatively large facial surface area. In some embodiments, the facial surface area of the mask is at least 10 square micrometers; at least 100 square micrometers; at least 1000 square micrometers; at least 10,000 square micrometers; at least 100,000 square micrometers; at least 0.01 square centimeters; at least 0.1 square centimeters; at least 1 square centimeter; at least 10 square centimeters; or at least 100 square centimeters (and/or, up to 100 square centimeters; up to 1,000 square centimeters; up to 10,000 square centimeters, or more). Combinations of these ranges are also possible.

As noted above, the epitaxial layer can be grown over the structure comprising the crystalline substrate and the mask. The epitaxial layer can be grown via any of a variety of epitaxial growth techniques. In some embodiments, the epitaxial growth can be homoepitaxial growth. In other embodiments, the epitaxial growth can be heteroepitaxial growth. In some embodiments, the epitaxial layer can be grown using chemical vapor deposition (CVD) and/or physical vapor deposition (PVD). The growth of the epitaxial layer may rely on the structure comprising the crystalline substrate and the mask as a seed for crystal growth. For example, in some embodiments, the crystalline substrate acts as a seed for crystal growth of the epitaxial layer. In some embodiments, the growth of the epitaxial layer may initiate directly over the crystalline substrate growing in a direction orthogonal to the geometric plane parallel to at least one in the {100} family of planes on the crystalline substrate, between the plurality of elongated domains. In some embodiments, after the growth of the epitaxial layer has exceeded the thickness of the mask, the epitaxial layer may grow laterally and merge into a single layer. In some embodiments, the epitaxial layer is planar.

In some embodiments, the epitaxial layer can be grown over a relatively large facial surface area. In some embodiments, the epitaxial layer is grown over a facial surface area of at least 10 square micrometers; at least 100 square micrometers; at least 1000 square micrometers; at least 10,000 square micrometers; at least 100,000 square micrometers; at least 0.01 square centimeters; at least 0.1 square centimeters; at least 1 square centimeter; at least 10 square centimeters; or at least 100 square centimeters (and/or, up to 100 square centimeters; up to 1,000 square centimeters; up to 10,000 square centimeters, or more). Combinations of these ranges are also possible.

When a structure (e.g., a layer) is referred to as being “on,” “over,” or “overlying” another structure (e.g., a layer or a substrate), it is over at least a portion of that structure. In some cases, a structure that is referred to as being “on,” “over,” or “overlying” another structure is over the entirety of that structure. When a structure (e.g., a layer) is referred to as being “on,” “over,” or “overlying” another structure (e.g., a layer or a substrate), it can be directly on the structure, or an intervening structure (e.g., a layer) also may be present. A structure that is “directly on” or “in direct contact with” another structure means that no intervening structure is present. It should also be understood that when a structure is referred to as being “on” or “over” another structure, it may cover the entire structure, or a portion of the structure. In addition, when a structure is referred to as being “on” or “over” another structure, it may be embedded within that structure. When a structure (e.g., a layer or a substrate) is referred to as being “on,” “over,” or “overlying” another structure, it can be above that other structure or below that other structure.

As noted above, systems and methods described herein can be used for growing epitaxial layers. The epitaxial layer can comprise a crystalline material. In some embodiments, the epitaxial is made up of a single crystalline domain. In some embodiments, the epitaxial layer has a diamond cubic crystal structure and/or a zinc blende crystal structure.

In some embodiments, the epitaxial layer can have no polarity (e.g., IV materials). In some embodiments, the epitaxial layer can have a polarity (e.g., III-V materials). In certain embodiments, the epitaxial layer has a different polarity than that of the crystalline substrate (e.g., by growing a compound semiconductor epitaxially on an elemental crystalline substrate). The methods described herein may advantageously grow epitaxial layers with a polarity mismatch with the crystalline substrate with a relatively low amount of anti-phase boundaries. In some embodiments, the epitaxial layer can have a lattice mismatch with the crystalline substrate (e.g., a InGaAs epitaxial layer on a Ge crystalline substrate). In some embodiments, the lattice mismatch between the crystalline substrate and the epitaxial layer can be at least 1%, at least 2.5%, at least 5%, at least 7.5%, at least 10%, or more. In some embodiments, the lattice mismatch between the crystalline substrate and the epitaxial layer can be less than or equal 80%, less than or equal to 50%, less than or equal to 25%, less than or equal to 20%, less than or equal to 15%, less than or equal to 12.5%, less than or equal to 10%, less than or equal to 7.5%, or less. Combinations of these ranges are also possible (e.g., at least 1% and less than or equal to 80%). Methods described herein may, in certain embodiments, advantageously grow epitaxial layers with a lattice mismatch with the crystalline substrate with a relatively low number of defects.

The epitaxial layer may be made of any of a variety of materials. In some embodiments, the crystalline structure of the epitaxial layer is made of a group V element such as silicon, germanium, carbon (e.g., diamond), or α-tin. In certain embodiments, the crystalline structure of the epitaxial layer is made of a compound semiconductor. For example, in some embodiments, the crystalline structure of the epitaxial layer is made of a III-V semiconductor (materials containing one or more Group III elements and one or more Group V elements), a II-VI semiconductor (materials containing one or more Group II elements and one or more Group VI elements, including but not limited to zinc selenide (ZnSe)), or I-VII semiconductors (materials containing one or more Group I elements and one or more Group VII elements). The epitaxial layer may include impurities. In some embodiments, at least 99 at %, at least 99.9 at %, at least 99.99 at %, at least 99.999 at %, at least 99.9999 at %, at least 99.99999 at % at least 99.99999 at %, at least 99.999999 at %, at least 99.999999 at %, at least 99.9999999 at %, or at least 99.99999999 at % of the epitaxial layer is made up of the materials that form the crystal structure of the epitaxial layer. In some such embodiments, the rest of the crystalline structure comprises other materials (e.g., dopants, impurities, etc.).

In certain embodiments, the crystalline structure of the epitaxial layer comprises a III-nitride material. The term “III-nitride material” is used herein to refer to any Group III element-nitride compound. Non-limiting examples of III-nitride materials include boron nitride (BN), aluminum nitride (AlN), gallium nitride (GaN), indium nitride (InN), and thallium nitride (TlN), as well as any alloys including Group III elements and Group V elements (e.g., AlₓGa₍₁₋ₓ₎N, AlₓIn_{y}Ga_{(1-x-y)}N, InₓGa₍₁₋ₓ₎N, AlₓIn₍₁₋ₓ₎N, GaAsₐPbN_{(1-a-b)}, AlₓIn_{y}Ga_{(1-x-y)}AsₐPbN_{(1-a-b)}, and the like). III-nitride materials may be doped n-type or p-type, or may be intrinsic.

In certain embodiments, the crystalline structure of the epitaxial layer comprises an aluminum nitride material. The phrase “aluminum nitride material” refers to aluminum nitride (AlN) and any of its alloys, such as aluminum gallium nitride (AlₓGa₍₁₋ₓ₎N), aluminum indium nitride (AlₓIn₍₁₋ₓ₎N), aluminum indium gallium nitride (AlₓIn_{y}Ga_{(1-x-y)}N), aluminum indium gallium arsenide phosphoride nitride (AlₓIn_{y}Ga_{(1-x-y)}AsₐPbN_{(1-a-b)}), and the like. In certain embodiments, the aluminum nitride material comprises AlN.

In certain embodiments, the crystalline structure of the epitaxial layer comprises a gallium nitride material. The phrase “gallium nitride material” refers to gallium nitride (GaN) and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphoride nitride (GaAsₐPbN_{(1-a-b)}), aluminum indium gallium arsenide phosphoride nitride (AlₓIn_{y}Ga_{(1-x-y)}AsₐP_{b}N_{(1-a-b)}), and the like. In certain embodiments, the gallium nitride material comprises GaN.

In certain embodiments, the crystalline structure of the epitaxial layer comprises a III-phosphide material. The term “III-phosphide material” is used herein to refer to any Group III element-phosphide compound. Non-limiting examples of III-phosphide materials include gallium phosphide (GaP), boron phosphide (BP), aluminum phosphide (AlP), indium phosphide (InP), and thallium phosphide (TlP), as well as any alloys including Group III elements and Group V elements (e.g., AlₓGa₍₁₋ₓ₎P, AlₓIn_{y}Ga_{(1-x-y)}P, InₓGa₍₁₋ₓ₎P, AlₓIn₍₁₋ₓ₎P, GaAsₐP_{b}N_{(1-a-b)}, AlₓIn_{y}Ga_{(1-x-y)}AsₐP_{b}N_{(1-a-b)}, and the like). III-phosphide materials may be doped n-type or p-type, or may be intrinsic.

In certain embodiments, the crystalline structure of the epitaxial layer comprises a III-arsenide material. The term “III-arsenide material” is used herein to refer to any Group III element-arsenide compound. Non-limiting examples of III-arsenide materials include gallium arsenide (GaAs), boron arsenide (Bas), aluminum arsenide (AlAs), as well as any alloys including Group III elements and Group V elements.

In some embodiments, the methods described herein comprise separating the epitaxial layer and the crystalline substrate from each other. In some embodiments, separating the epitaxial layer and the crystalline substrate can involve applying a force to the epitaxial layer, the crystalline substrate, or both. Separation of the epitaxial layer and the crystalline substrate can involve removing the epitaxial layer while leaving the substrate behind or removing the substrate while leaving the epitaxial layer behind.

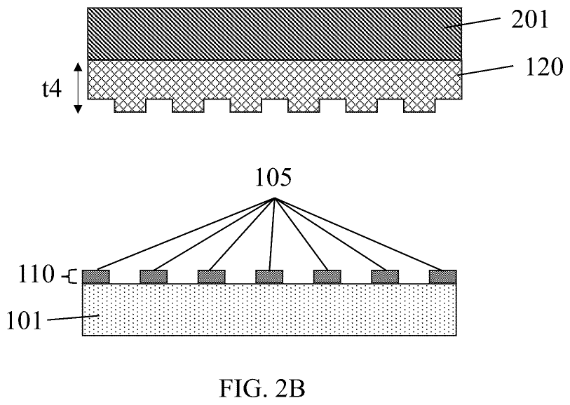

In some embodiments, the epitaxial layer can be exfoliated from the crystalline substrate. Mechanical exfoliation of the epitaxial layer may be implemented via the deposition of a stressor layer (e.g., a Ni stressor layer) to form a separated epitaxial layer. The stressor layer can have a relatively high internal stress that may facilitate the propagation of cracks during mechanical exfoliation. In some embodiments, the mask comprising the plurality of elongated domains reduces the interfacial toughness between the crystalline substrate and the epitaxial layer thereby readily allowing the separation of the epitaxial layer from the crystalline substrate. By controlling the thickness of the stressor layer and the internal stress, the mode of fracture may be controlled. For example, in FIGS. 2A and 2B, stressor layer 201 is deposited onto epitaxial layer 120 to facilitate mechanical exfoliation and separate structure 115 from separated epitaxial layer 120.

In certain embodiments, the epitaxial layer is separated from the crystalline leaving the mask over the crystalline substrate. In this manner, the crystalline substrate and the mask, can be reused multiple times (e.g., at least 2 times, at least 5 times, at least 10 times, at least 50 times, at least 100 times, at least 500 times, and/or, up to 1000 times, or more). For example, referring to FIG. 2B, in some embodiments, the structure that includes substrate 101 and mask 110 can be reused to grow a second epitaxial layer (e.g., using any of the methods described above or elsewhere herein). In some such embodiments, the second epitaxial layer and the substrate can subsequently be separated, leaving the substrate available for further reuse. By reusing the crystalline substrate and the mask, the average cost of each epitaxial layer may be reduced.

In certain cases, insufficient internal stress in the stressor layer and/or insufficient thickness of the stressor layer may lead to delamination of the stressor layer, which may prevent separation of the epitaxial layer from the crystalline substrate. On the other hand, excessive internal stress in the stressor layer and/or excessive thickness of the stressor layer may lead to spalling of the crystalline substrate thereby reducing the quality of the separated epitaxial layer. In certain embodiments, the thickness and/or material type of the stressor layer are selected such that the epitaxial layer is removed from the substrate without spalling of the crystalline substrate. In certain embodiments, the thickness and/or material type of the stressor layer are selected such that delamination of the stressor layer from the epitaxial layer is avoided. More information regarding the influence of the stressor layer on crack propagation can be found in the published manuscript: Kim, H., Lee, S., Shin, J. et al. “Graphene nanopattern as a universal epitaxy platform for single-crystal membrane production and defect reduction,” Nat. Nanotechnol. 17, 1054-1059 (2022). https://doi.org/10.1038/s41565-022-01200-6, and its corresponding Supplementary Information, which is incorporated herein by reference in its entirety for all purposes.

In some embodiments, the epitaxial layer is separated from the structure to form a separated epitaxial layer. In some embodiments, the epitaxial layer (while on the growth substrate and/or after separation from the growth substrate) has a thickness that is relatively low. In the embodiment shown in FIG. 2B, separated epitaxial layer 120 has thickness t4. In certain embodiments, the thickness of the epitaxial layer (while on the growth substrate and/or after separation from the growth substrate) is greater than or equal to 50 nm, greater than or equal to 100 nm, greater than or equal to 250 nm, greater than or equal to 500 nm, greater than or equal to 750 nm, greater than or equal to 1 micrometer, greater than or equal to 5 micrometers, greater than or equal to 10 micrometers, or greater than or equal to 50 micrometers. In some embodiments, the thickness of the epitaxial layer (while on the growth substrate and/or after separation from the growth substrate) can be less than or equal to 50 micrometers, less than or equal to 10 micrometers, less than or equal to 5 micrometers, less than or equal to 1 micrometer, less than or equal to 750 nm, less than or equal to 500 nm, less than or equal to 250 nm, less than or equal to 100 nm, or less than or equal to 50 nm. Combinations of these ranges are also possible (e.g., greater than or equal to 50 nm and less than or equal to 50 micrometers).

In some embodiments, the separated epitaxial layer can be or can be made into a freestanding layer. A layer is considered to be “freestanding,” as that term is used herein, when it is not bound to an adjacent substrate. For example, in FIG. 2B, stressor layer 201 facilitates mechanical exfoliation to form separated epitaxial layer 120, and stressor layer can be etched away or otherwise removed from the epitaxial layer to produce a freestanding epitaxial layer. It should be noted that a freestanding layer can be in contact with another material (e.g., a substrate) and still be freestanding, as long as the freestanding layer is not bound to the other material. For example, a layer that is in contact with an adjacent substrate and that can be removed from that substrate without damaging the layer or the substrate would still be considered a freestanding layer.

In some embodiments, the epitaxial layer (while on the growth substrate and/or after separation from the growth substrate) comprises a relatively low number of defects. Arranging the mask such that it comprises a plurality of elongated domains parallel or substantially parallel to a direction in the <110> family of direction of the crystalline substrate, the epitaxial layer, or both may reduce the presence of defects (e.g., edge dislocations, screw dislocations, and/or anti-phase boundaries). Without wishing to be bound to any particular theory, the plurality of elongated domains may periodically cover step edges on the crystalline substrate that generally occur along the <110> family of directions for any of a variety of diamond cubic crystal structures and/or zinc blende crystal structures. It is believed that, in order for certain defects to form, such as anti-phase boundaries, at least two step edges may coexist between each of the plurality of elongated domains and the nearest neighbor. The geometric dimensions of the plurality of elongated domains may reduce and/or prevent such defects from forming by reducing the existence of more than step edge per distance between each of the elongated domain and the nearest neighbor.

In some embodiments, the epitaxial layer (while on the growth substrate and/or after separation from the growth substrate) comprises a relatively large facial surface area. The facial surface area, in this context, is the surface area of the face of the epitaxial layer that faces outward from the substrate. For example, referring to FIG. 1E, in some embodiments, the surface area of surface 130 can be relatively large. In some embodiments, the facial surface area of the epitaxial layer (while on the growth substrate and/or after separation from the growth substrate) is at least 10 square micrometers; at least 100 square micrometers; at least 1000 square micrometers; at least 10,000 square micrometers; at least 100,000 square micrometers; at least 0.01 square centimeters; at least 0.1 square centimeters; at least 1 square centimeter; at least 10 square centimeters; or at least 100 square centimeters (and/or, up to 100 square centimeters; up to 1,000 square centimeters; up to 10,000 square centimeters, or more). Combinations of these ranges are also possible.

In some embodiments, the epitaxial layer (while on the growth substrate and/or after separation from the growth substrate) advantageously comprises a relatively low threading dislocation density. In some embodiments, the epitaxial layer (while on the growth substrate and/or after separation from the growth substrate) comprises a threading dislocation density of less than or equal to 10⁹ threading dislocations per cm², less than or equal to 10⁸ threading dislocations per cm², less than or equal to 10⁷ threading dislocations per cm², less than or equal to 10⁶ threading dislocations per cm², less than or equal to 10⁵ threading dislocations per cm², less than or equal to 10⁴ threading dislocations per cm², less than or equal to 1,000 threading dislocations per cm², less than or equal to 100 threading dislocations per cm², or less than or equal to 10 threading dislocations per cm². In some embodiments, the epitaxial layer (while on the growth substrate and/or after separation from the growth substrate) comprises a threading dislocation density of greater than or equal to 1 threading dislocation per cm², greater than or equal to 10 threading dislocations per cm², greater than or equal to 100 threading dislocations per cm², greater than or equal to 1,000 threading dislocations per cm², greater than or equal to 10⁴ threading dislocations per cm², or greater than or equal to 105 threading dislocations per cm². Combinations of these ranges are also possible (e.g., less than or equal to 10⁹ threading dislocations per cm² and greater than or equal to 1 threading dislocations per cm²).

In some embodiments, the epitaxial layer (while on the growth substrate and/or after separation from the growth substrate) advantageously comprises a relatively low anti-phase domain density. In some embodiments, the epitaxial layer (while on the growth substrate and/or after separation from the growth substrate) comprises a surface anti-phase domain density of less than or equal to 10⁷ anti-phase domains per cm², less than or equal to 10⁶ anti-phase domains per cm², less than or equal to 105 anti-phase domains per cm², less than or equal to 10⁴ anti-phase domains per cm 2, less than or equal to 1,000 anti-phase domains per cm², less than or equal to 100 ani-phase domains per cm², less than or equal to 10 anti-phase domains per cm², less than or equal to 5 anti-phase domains per cm², less than or equal to 1 anti-phase domain per cm², or no anti-phase domains per cm². In certain embodiments, the epitaxial layer can contain less than or equal to 100, less than or equal to 10, less than or equal to 5, less than or equal to 2, less than or equal to 1, or no anti-phase boundaries per cubic centimeter. The relatively low number of anti-phase boundaries and the relatively low surface anti-phase domain density may lead to improved device performance. For example, a light-emitting diode comprising the separated epitaxial layer may exhibit higher electroluminescence and/or lower forward bias recombination current than a light-emitting diode not comprising the separated epitaxial under otherwise identical conditions.

In certain embodiments, methods described herein further comprise integrating the epitaxial layer into an electronic device. For example, in some embodiments, after epitaxial layer 120 and substrate 1011 have been separated from each other, and epitaxial layer 120 can be integrated into an electronic device. In some such embodiments, stressor layer 201 can be removed from epitaxial layer 120 (e.g., before, during, or after integration of epitaxial layer 120 into the electronic device). In some embodiments, the method further comprises integrating the epitaxial layer into a diode (e.g., a light emitting diode). In some embodiments, the method further comprises integrating the epitaxial layer into a transistor (e.g., a field effect transistor). In some embodiments, the method further comprises integrating the epitaxial layer into a rectifier.

The following publications and patent applications are incorporated herein by reference in their entirety for all purposes: Kim, H., Lee, S., Shin, J. et al. “Graphene nanopattern as a universal epitaxy platform for single-crystal membrane production and defect reduction.” Nat. Nanotechnol. 17, 1054-1059 (2022). https://doi.org/10.1038/s41565-022-01200-6, and its corresponding Supplementary Information; Sui, Z. and Hutchinson, J. W., “Steady-State Cracking in Brittle Substrates Beneath Adherent Films,” Int. J. Solids Structures, Vol. 25, No. 11, pp. 1337-1353, 1989; U.S. Patent Application Publication No. 2020-0286786 A1, published on Sep. 10, 2020, and filed as International Patent Application No. PCT/US2018/060945 on Nov. 14, 2018, entitled “Epitaxial Growth and Transfer via Patterned Two-dimensional (2D) layers”; and U.S. Pat. No. 10,770,289 to Kim, issued Sep. 8, 2020, and entitled “Systems and Methods for Graphene Based Layer Transfer.”

The following example is intended to illustrate certain embodiments of the present invention but does not exemplify the full scope of the invention.

### EXAMPLE

This example describes the growth of various epitaxial materials on substrates using graphene as a mask material, in accordance with certain embodiments. It was observed that growing epitaxial layers over graphene masks having elongated graphene domains aligned along <110> directions resulted in a substantial reduction in defects. The introduction of patterned graphene can also aid in exfoliating the epitaxial layer from the substrate (as opposed to spalling the substrate and/or delaminating the stressor material from the epitaxial material).

Formation of graphene was conducted as follows.

For Ge substrates, graphene was grown directly on Ge(100) by CVD (TCVD-50B, Graphene Square Inc.) at atmospheric pressure. Ge(100) wafers were first cleaned in a diluted HCl solution (10% HCl in water) for 3 minutes, followed by a water rinse and a nitrogen blow-dry. After loading Ge substrates into the CVD system, the CVD tube was first purged with Ar for 30 minutes at room temperature, followed by a temperature ramp up to 910° C. which took 30 minutes. At 910° C., graphene was grown by flowing H₂ of 730 sccm and CH₄ of 200 sccm for 60 minutes. After the growth, the tube was cooled to room temperature via an argon flow of 140 sccm. The graphene thickness obtained was between monolayer and bilayer.

For III-V substrates, graphene was first formed on a copper foil by CVD, followed by a standard wet transfer process to transfer the graphene onto the III-V substrate. GaAs substrates were deoxidized by a diluted HCl, and InP substrates by a 5:1 buffered oxide etchant (BOE; J.T. Baker, USA), and both were cleaned with water right before scooping the graphene. Because remote epitaxy of III-V requires dry-transferred graphene and does not work on wet-transferred graphene due to interfacial oxidation, employing wet-transferred graphene in this study ensured that the growth of single-crystalline membranes is the result of a purely lateral overgrowth, not by a mixed growth mode with a portion of remote epitaxy.

Patterning of the graphene mask was conducted as follows.

After the graphene formation, graphene was patterned at the nanoscale by various types of lithographic methods, including e-beam lithography, interference lithography, and stepper lithography. E-beam lithography was mainly used to study the epitaxial film growth and exfoliation behavior, depending on the pattern geometries. 200 nm-thick polymethyl methacrylate (PMMA) resist layer was spin-coated on graphene and baked at 180° C. for 2 min, followed by exposure using Elionix ELS-F125 e-beam lithography system. Exposed samples were then developed in a 1:3 ratio of methyl isobutyl ketone (MIBK):isopropanol (IPA) for 60 s and washed out in pure IPA. Developed PMMA patterns were transferred to graphene by reactive ion etching (RIE) via Plasma-Therm 790 with 02 (20 s, 6 mTorr, 90 W), followed by rinsing of the overlying PMMA layer in acetone to finish graphene patterning process. For large-area thin film growths and LED device fabrication, interference lithography or stepper lithography was employed to produce millimeter- to centimeter-scale patterns. Nanoscale gratings were interferometrically or photolithographically patterned utilizing the interference pattern of 325 nm HeCd laser generated by the Lloyds-mirror lithographic system or exposing in GCA AS200 i-line Stepper, respectively. For both processes, 100 nm-thick positive photoresist (Futurrex PR1-100A1) was first spin-coated on graphene and baked at 120° C. for 2 min. After exposure, the samples are developed in Futurrex RD6 diluted at 3:1 with deionized (DI) water for 15 s and rinsed in pure DI water. The rest of the process was the same as e-beam lithography.

Epitaxial growth was conducted as follows.

Ge, GaAs, and InAs epitaxy were conducted in a close-coupled showerhead MOCVD reactor using arsine, trimethylgallium, trimethylaluminum, trimethylindium, and germane as sources of As, Ga, Al, In, and Ge, respectively. Disilane and dimethylzinc were used as Si and Zn dopants, respectively. The reactor pressure was kept at 100 Torr during the growth, and nitrogen was used as a carrier gas. Ge growth was conducted at 650° C. with a growth rate of about 30 nm/min. GaAs growth was conducted at 650° C. with a growth rate of about 33 nm/min and a V/III flow rate ratio of about 45. InAs growth was conducted at 650° C. with a growth rate of about 23 nm/min and a V/III flow rate ratio of about 65. For the growth on GaAs and InP substrates, arsine and phosphine were respectively flown during the temperature ramp-up from 300° C. to the growth temperature to prevent substrate desorption before the growth. Similarly, after the growth of GaAs and InAs films, arsine was flowed during the temperature ramp-down to 300° C. For the growth of red LED structures, a 2 μm-thick GaAs buffer was first grown at 650° C., followed by a 700 nm-thick p-GaAs bottom contact layer, 350 nm-thick p-Al_{0.65}Ga_{0.35}As barrier, 300 nm-thick Al_{0.35}Ga_{0.65}As emitter, 350 nm-thick n-Al_{0.65}Ga_{0.35}As barrier, and 100 nm-thick n-GaAs top contact layer at 700° C. Although p-GaAs was more commonly used as a top contact layer, n-GaAs was employed as a thin top contact layer and p-GaAs as a thick bottom contact layer because an additional current spreading scheme was not employed and both holes and electrons were laterally injected.

Two-dimensional layer transfer and device fabrication were conducted as follows.

The grown films were exfoliated by first depositing a 30 nm-thick Ti adhesion layer by e-beam evaporation, with a deposition rate of about 0.1 nm/sec. Next, a Ni stressor layer was deposited by direct current (DC) sputtering in the same chamber with a DC power of 500 W and a constant Ar flow of 6 sccm. The stress level of Ni was controlled by the chamber pressure during the sputtering, which typically ranged around 1.1-1.8 mTorr, with a higher pressure resulting in a higher stress level. After the deposition of metal, a thermally releasable tape (TRT; Revalpha, release temperature about 150° C.; Semiconductor Equipment Corp., USA) was attached to the metal via gently rubbing with a cotton swab. The tape edge was then lifted up by holding with a tweezer, which propagates cracks from the sample edge. The cracks propagated as the tape was further lifted up, and the mechanical exfoliation finished when the entire TRT/stressor/epilayer stack was detached from the substrate.

Exfoliated AlGaAs LED layer on TRT was transferred onto a Si wafer by treating with oxygen plasma (Anatech Barrel Plasma System), spin-coating 1 vol % aqueous solution of (3-Aminopropyl)triethoxysilane (APTES; Sigma-Aldrich, USA) at a speed of 3000 rpm for 30 seconds, and baking at 110° C. for 1 minute on both LED and receiver substrate surfaces. The substrate was subsequently spin-coated with polyimide precursor (PI-2545; HD Microsystems, USA) at a speed of 3000 rpm for 30 seconds, baked at 110° C. for 30 seconds, bonded with the LED film on TRT and pressed in steel vise (Toomaker's vise; Tormach, Inc., USA), and baked further at 180° C. for 10 minutes before TRT was removed. Final curing in a 250° C. convection oven completed the transfer process. Wet etching in FeCl₃ solution (MG Chemicals, Canada) and in 5:1 BOE removed Ti/Ni layers.

LED mesa structures were fabricated by photolithography and reactive ion etching (RIE; PlasmaPro 100 Cobra 300 System; Oxford Instruments, UK) in Cl₂ gas. Both the top and bottom metal contact pads were formed by photolithography, electron-beam evaporation of Cr/Au (about 15/100 nm), and metal lift-off.

Various characterizations of the layers and devices were carried out.

Cross-sectional STEM specimens were prepared with conventional focused ion beam lift-out technique using Helios NanoLab 600. Argon ion milling under 900 and 500 eV was used to clean the surface amorphous layer and minimize subsurface damage.

STEM images were collected using a probe-aberration corrected Thermo Fisher Scientific Themis Z S/TEM operated at 300 kV, 20 mrad convergence semi-angle. Strain mapping of the film with respect to the substrate was conducted using GPA based on atomic resolution images.

Atomic force microscopy (AFM) measurements were conducted using an AFM probe with a silicon tip (PPP-NCHR, Nanosensors) by noncontact mode (Park NX10, Park Systems).

SEM and EBSD characterizations were conducted using a Zeiss Merlin high-resolution SEM system. SEM images were measured using a beam acceleration voltage of 3 kV and a current of 0.1 nA, and EBSD maps were measured using an EBSD detector with a beam acceleration voltage of 15 kV and a current of 3 nA.

Raman and EL spectra were measured using a Renishaw Invia Reflex Micro Raman system with a CCD detector, and I-V characteristics were measured using a Signatone Probe Station (Signatone Corp., USA) equipped with a semiconductor parameter analyzer (Agilent 4156C; Keysight Technologies, USA) and a camera system connected with an optical microscope for collecting images.

Epitaxial layers were produced and separated from substrates as follows.

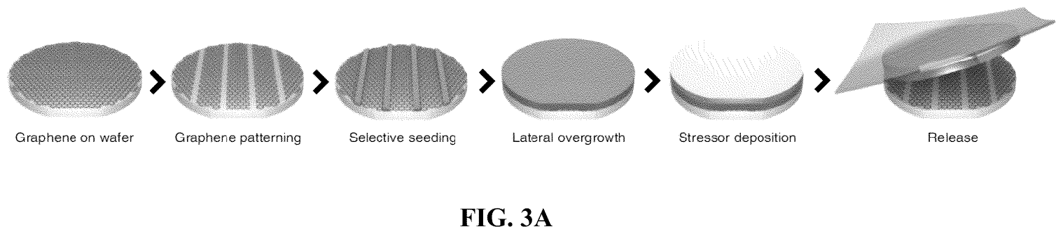

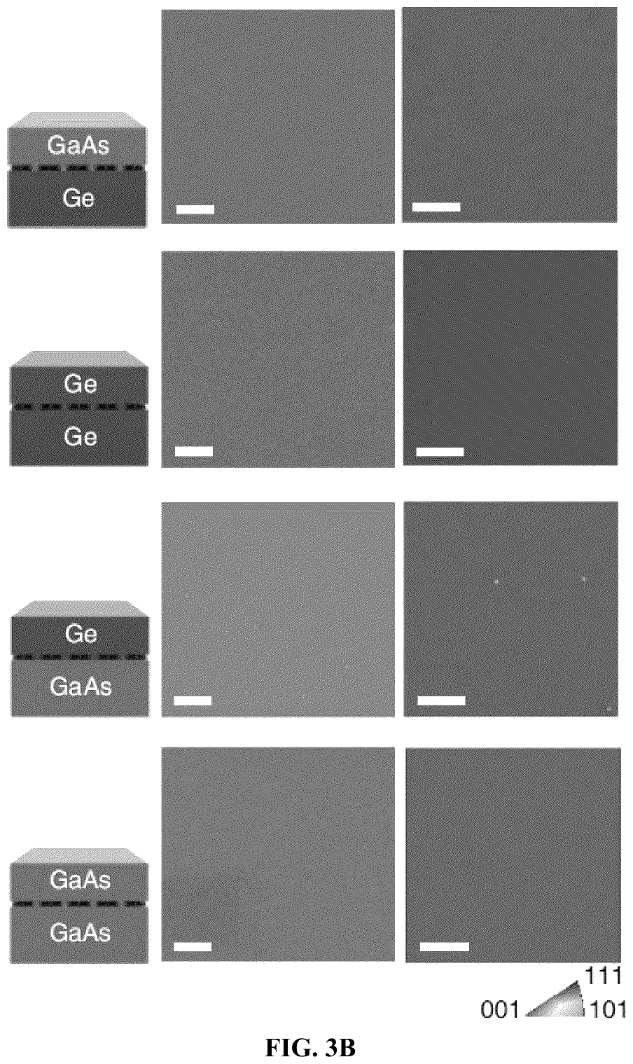

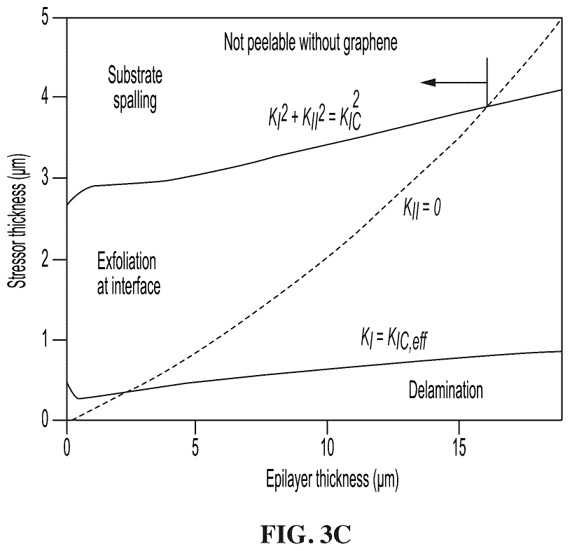

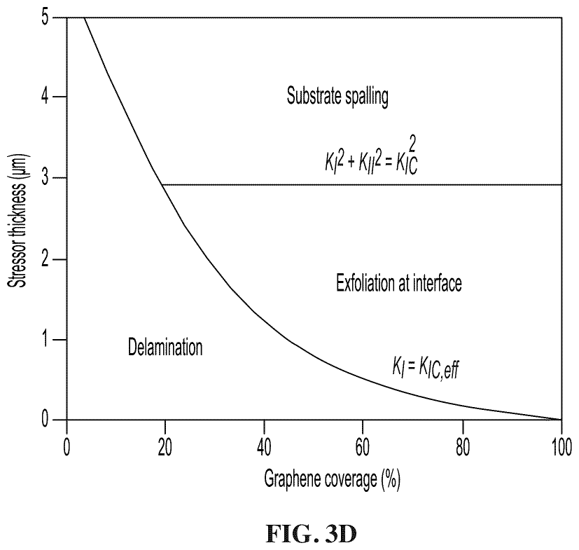

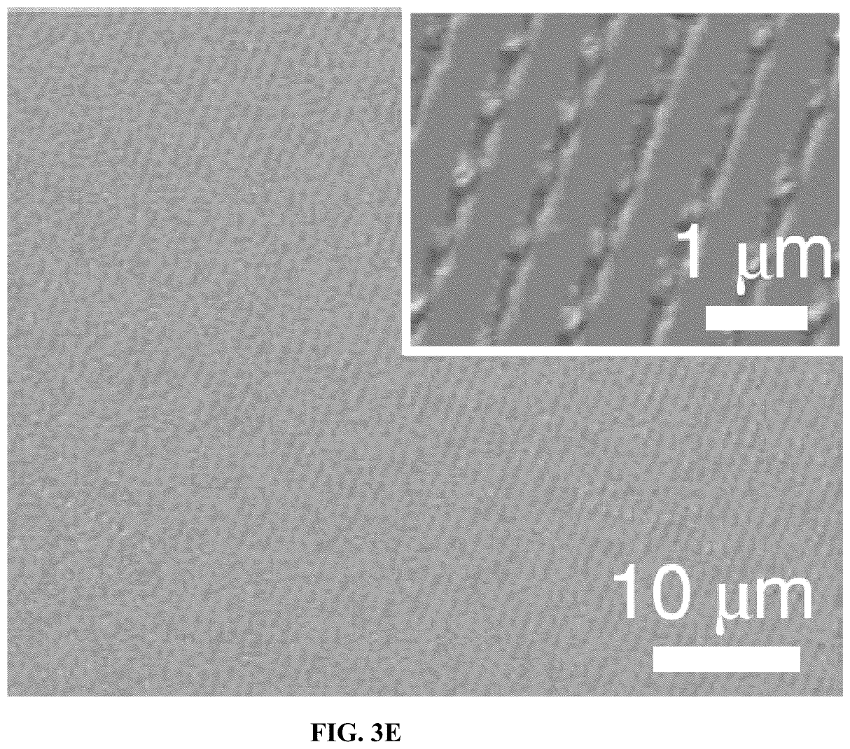

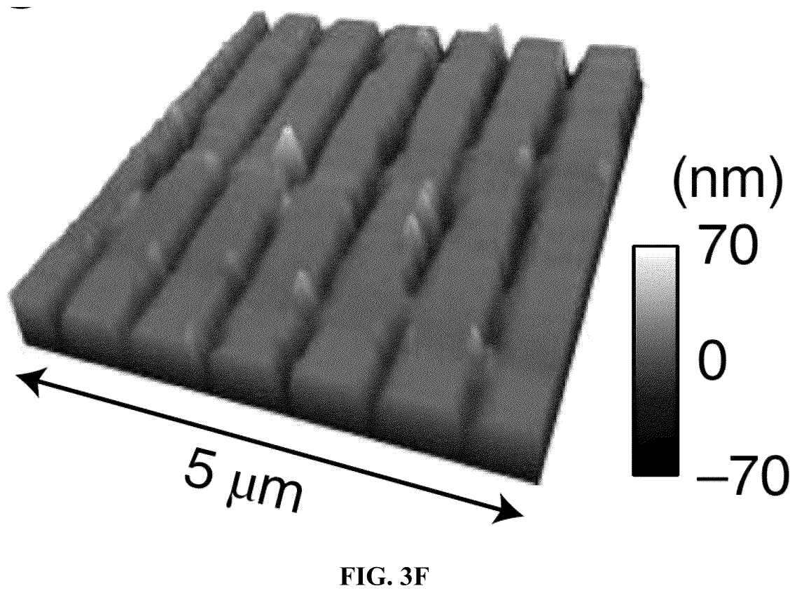

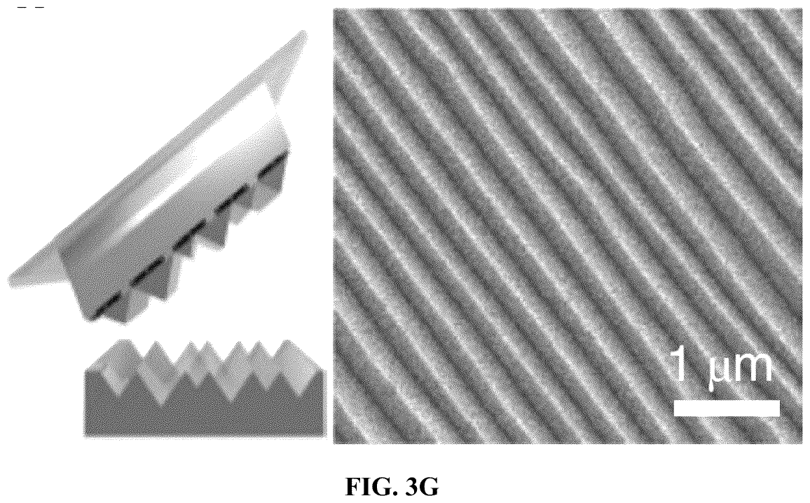

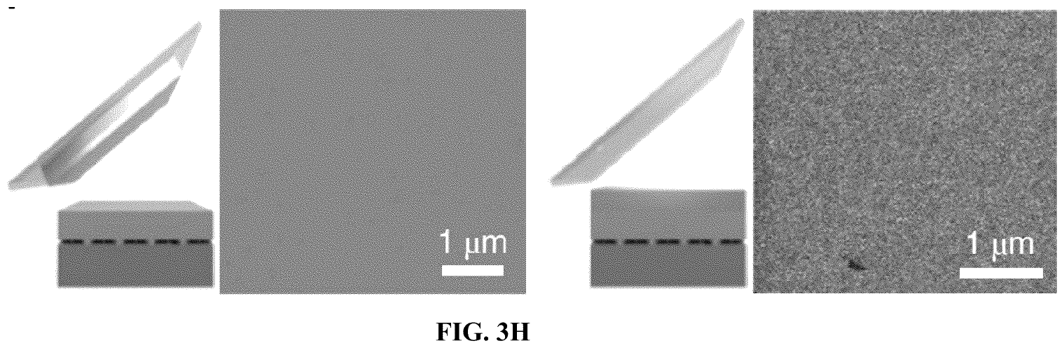

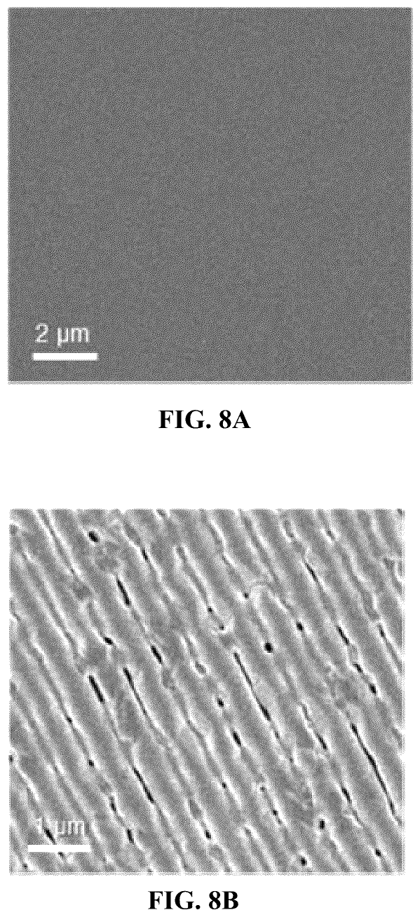

FIG. 3A shows schematics of the process flow for epitaxy on graphene nanopatterns (EPG) and release of the epilayers. Graphene-coated Ge(100) substrates were used as a growth template, on which Ge and GaAs (that are lattice-matched) were grown through graphene stripes. Graphene was first grown on an on-axis Ge substrate, followed by lithography and dry etching. The growth of Ge and GaAs on GaAs wafers through patterned graphene was also studied. The scanning electron microscopy (SEM) images in FIG. 3B show that Ge and GaAs films grown by metal-organic chemical vapor deposition (MOCVD) were fully planarized after growing a nominally 1 μm-thick film. The electron backscatter diffraction (EBSD) maps and X-ray diffraction (XRD) characterizations revealed that the entire film was single-crystalline (FIG. 3B). Without wishing to be bound by any particular theory, it is believed that this was due to the selectivity for the exposed region over the graphene-coated region. The mergence and planarization of the film from the patterns were governed by the pattern geometry and crystal orientation-dependent growth rates (see FIGS. 8A and 8B).

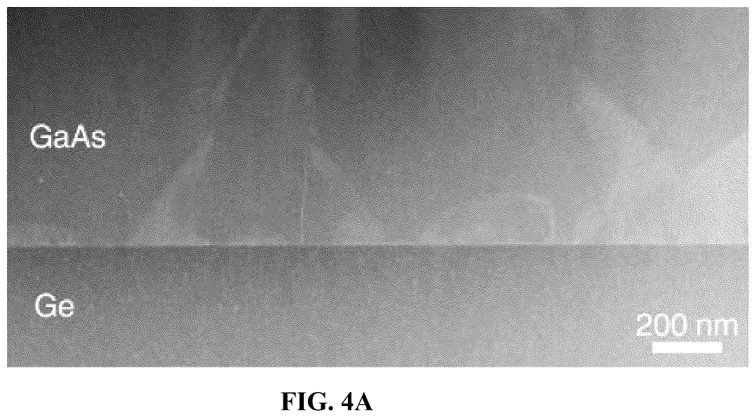

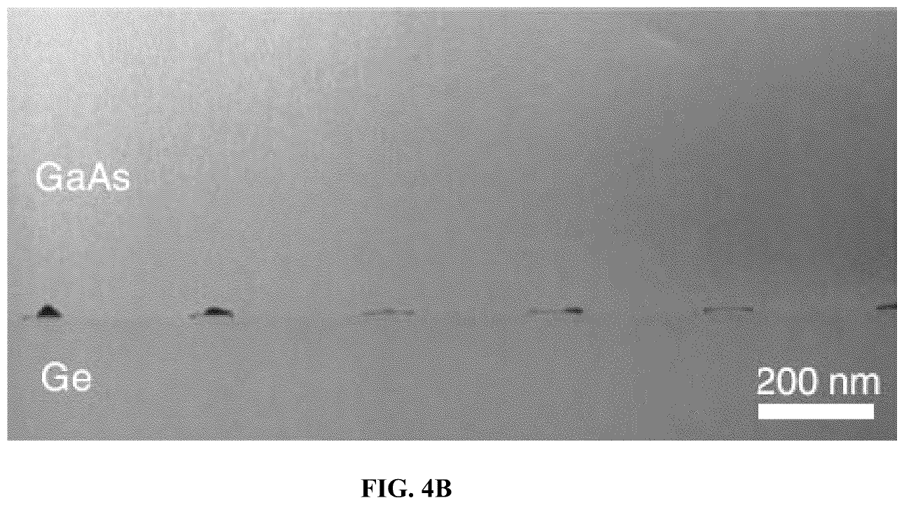

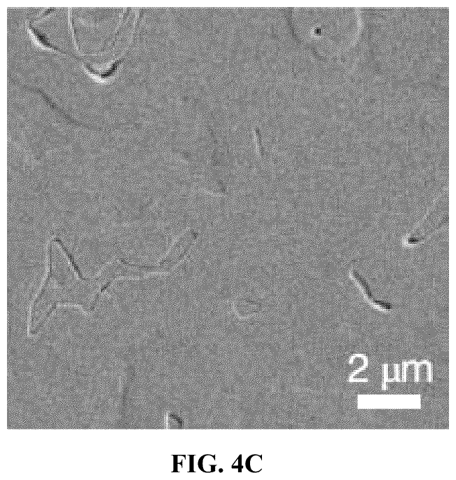

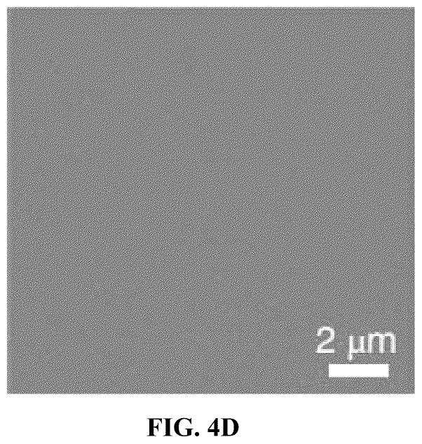

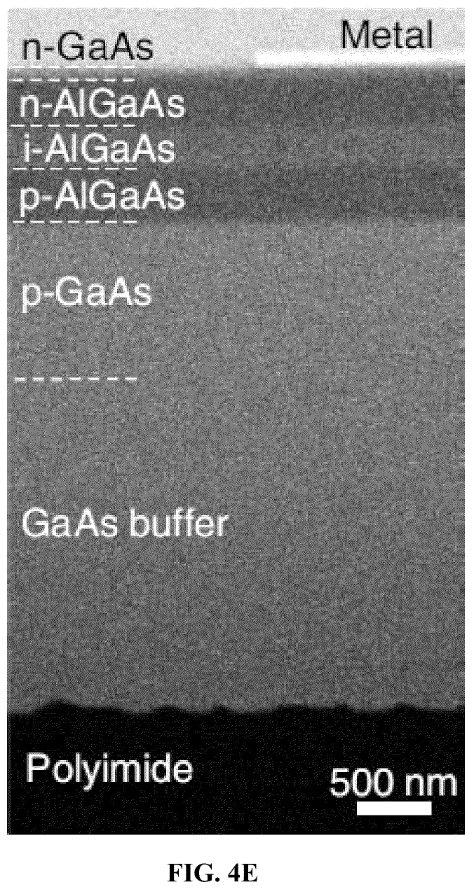

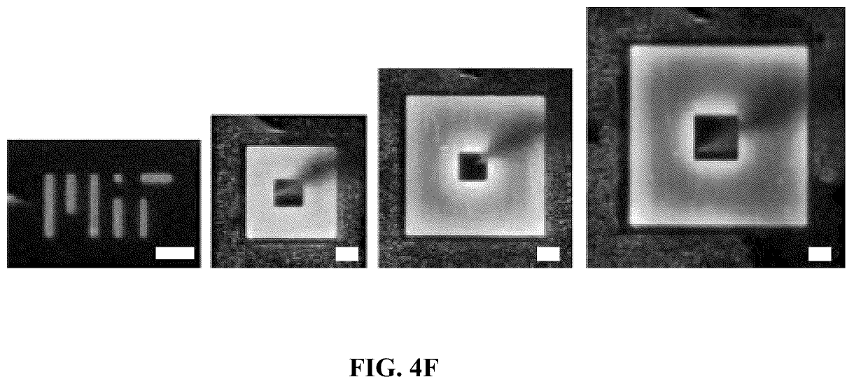

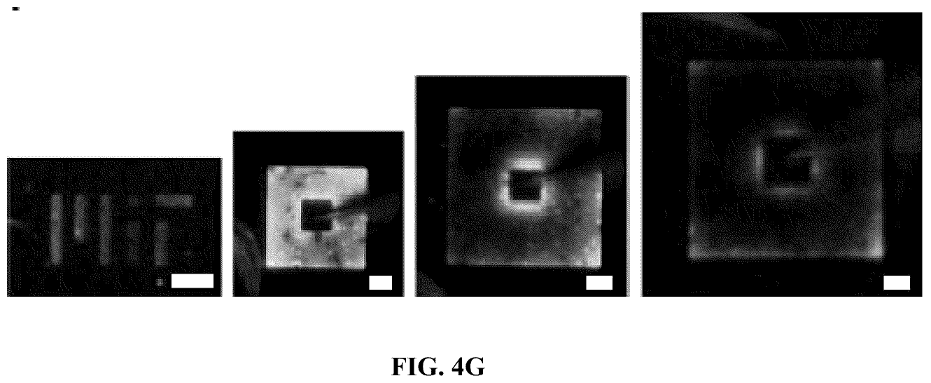

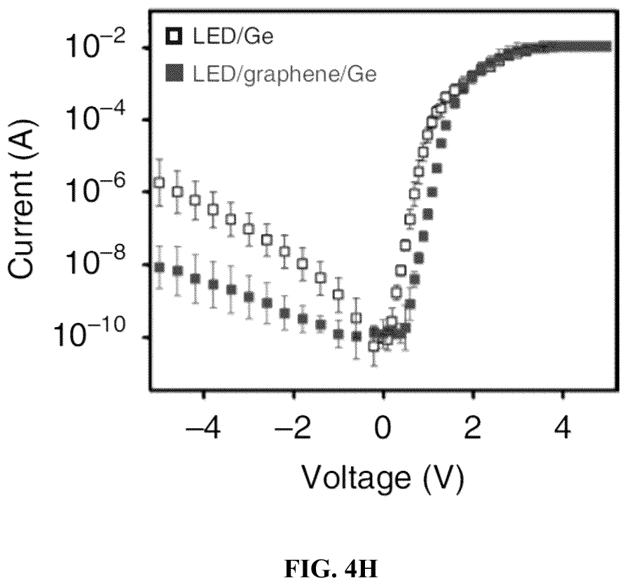

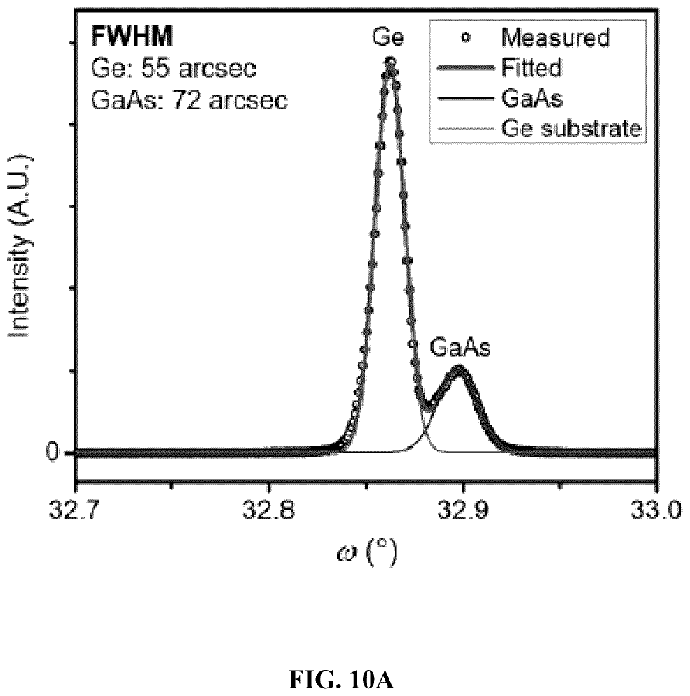

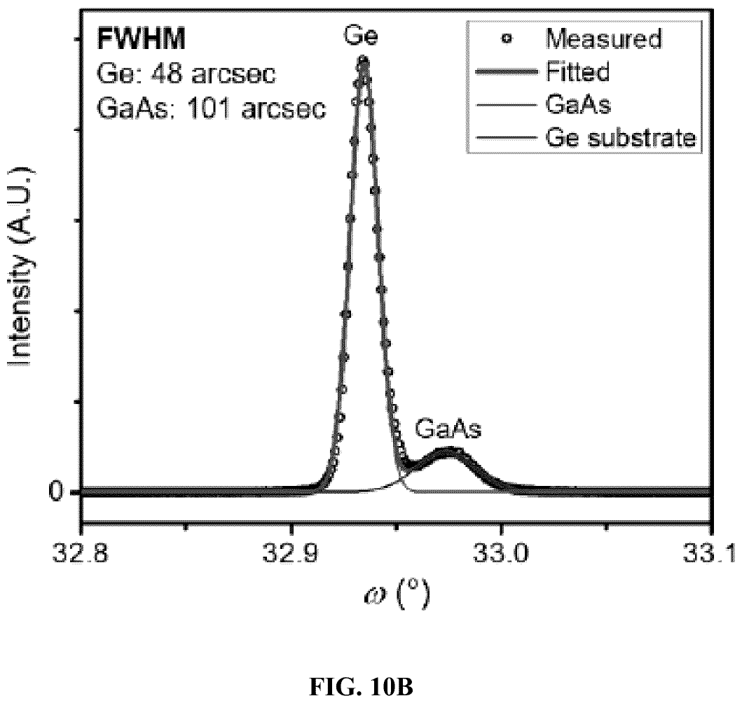

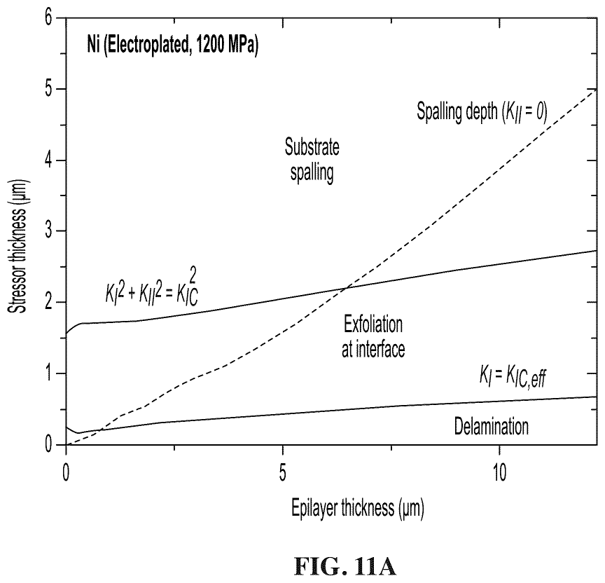

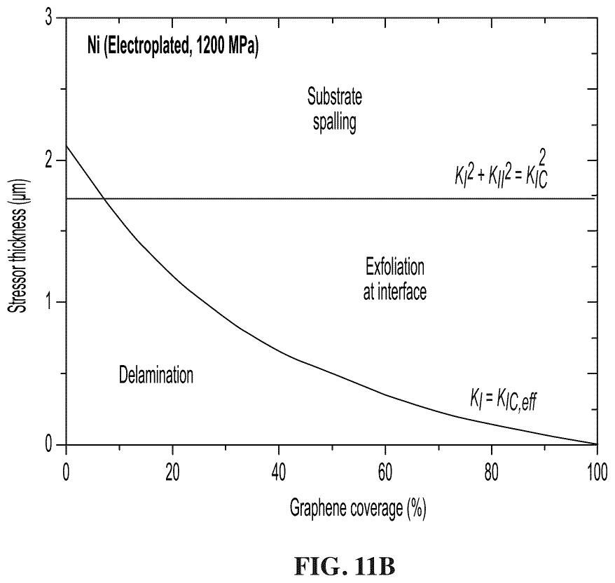

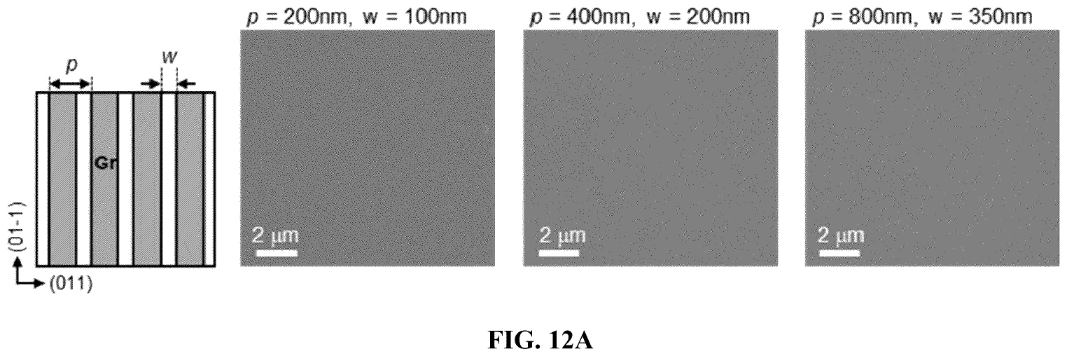

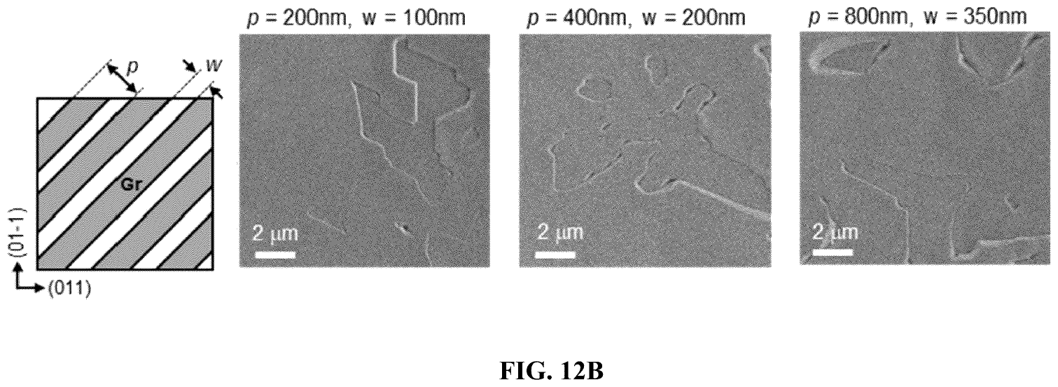

The EPG technique can be shown to eliminate the formation of APBs in III-V epilayers. The formation of APBs is unavoidable in conventional III-V epitaxy on elemental substrates of on-axis (100) orientation due to the presence of monoatomic steps on the surface. Thus, APBs were clearly observed when GaAs is directly grown on Ge(100), as shown in FIG. 4A. However, the EPG technique showed complete elimination of APBs when the alignment of graphene stripes was along <110> directions of Ge surfaces. As shown in FIGS. 3B and 4B, the GaAs film grown on graphene stripes aligned to <110> directions exhibited no APB. The enhancement of crystal quality by APB elimination is also confirmed by XRD characterizations (FIGS. 10A and 10B). Interestingly, APBs still appeared for GaAs on graphene patterned along <100> directions (FIGS. 11A and 11B). One possible cause for this is that step edges tend to form along <110> directions due to surface reconstruction, and such <110> steps can be periodically covered by graphene patterns along the <110> directions. In order for APBs to form from graphene nanopatterns, more than two step edges need to co-exist on the exposed region between two graphene stripes, which is unlikely to occur with the aforementioned pattern dimensions.

The Impact of APB elimination was shown by comparing optoelectronic and electronic performances of III-V devices. AlGaAs-based red light-emitting diodes (LEDs) grown on patterned graphene were APB-free while those directly grown on Ge exhibited APBs in its microstructures (FIGS. 4C and 4D). LED devices (see above for details) were fabricated, and a higher reverse-bias dark current and a higher forward-bias recombination current for LEDs with APBs directly grown on Ge (FIG. 4H) was observed, substantiating the superior material quality of APB-free LEDs grown on patterned graphene. This was also substantiated by electroluminescence (EL) measurements, which indicated a significantly brighter EL and efficient current spreading in LEDs grown on patterned graphene when compared with LEDs without graphene (FIG. 4F and FIG. 4G).

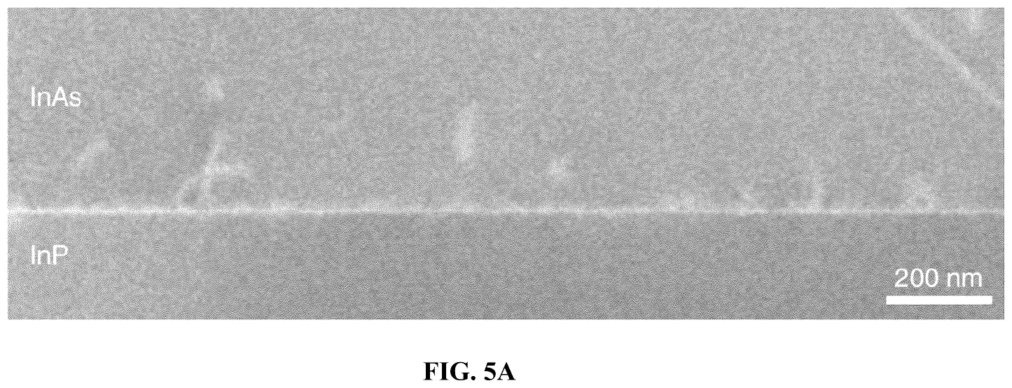

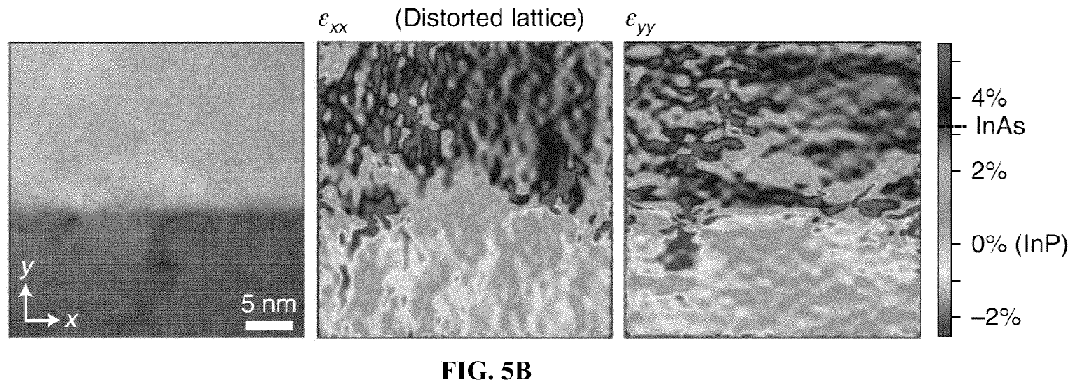

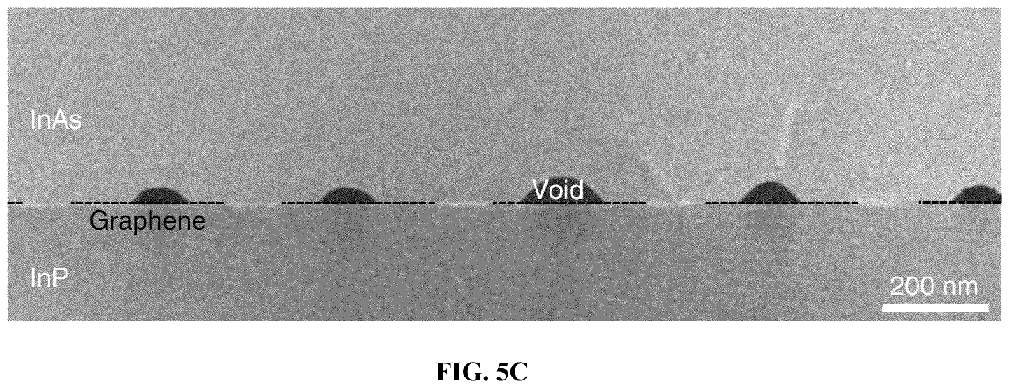

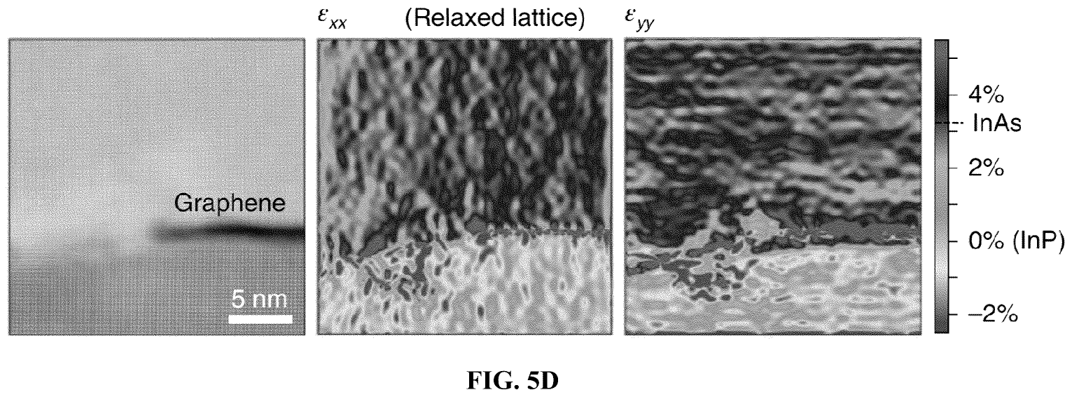

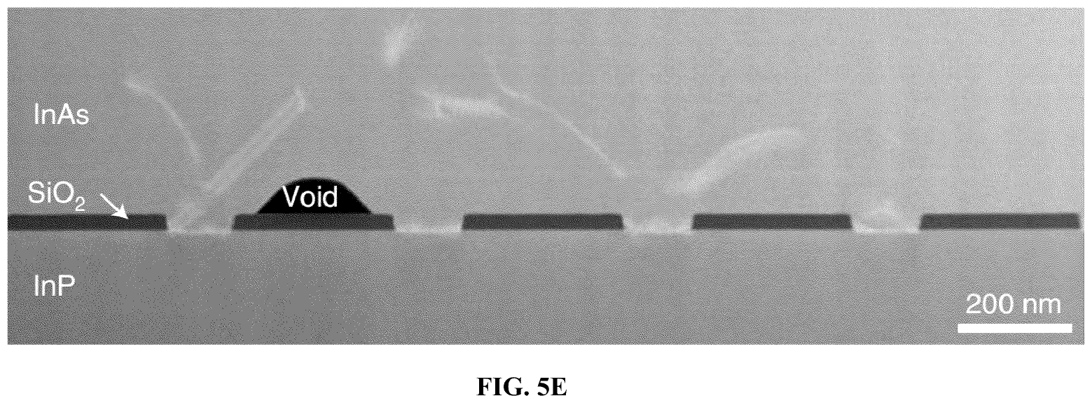

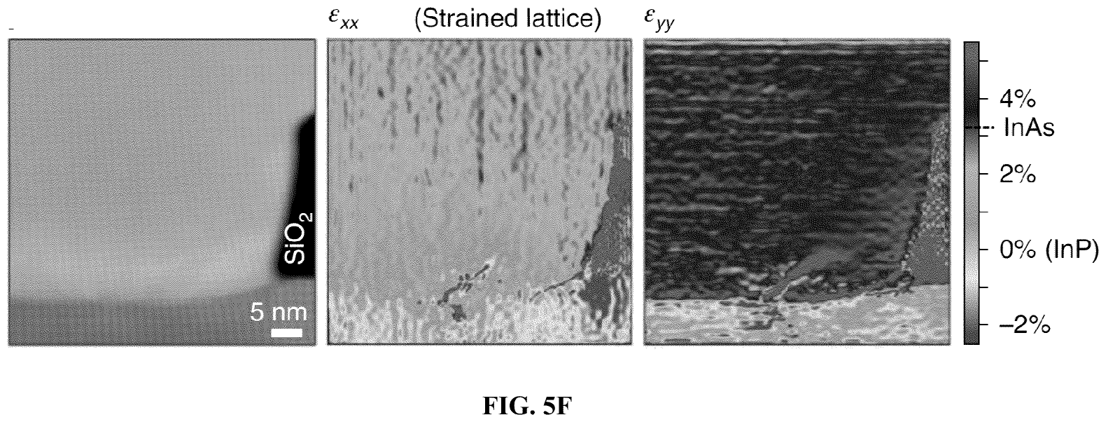

Defect reduction and strain relaxation in lattice-mismatched heteroepitaxial systems was also shown, which was conducted by theoretically and experimentally comparing heteroepitaxy on patterned graphene with direct heteroepitaxy and SiO₂ mask-based conventional selective-area epitaxy. Experimentally, the heteroepitaxy of InAs on InP substrates with 3.2% lattice-mismatch as a model system was studied. Heteroepitaxy was performed on both monolayer graphene and 30-nm-thick SiO₂ masks with the same mask width and periodicity. Compared to the case of direct growth of 1 μm-thick InAs on InP, a reduction of dislocations was observed for 1 μm-thick InAs grown on graphene patterns as shown in the scanning transmission electron microscopy (STEM) images in FIGS. 5A and 5B. Geometrical phase analysis (GPA) at the interfaces showed that the lattice near the interface was distorted in direct heteroepitaxy (FIG. B), whereas the strain was mostly relaxed near the edge of graphene (FIG. 5D). The high-resolution STEM image and GPA maps in FIG. 5D clearly show slight bending of graphene near the edge and complete relaxation of strain in the film above graphene, which substantiates the graphene's unique effect on dislocation reduction by its bendability and chemical inertness. On the other hand, SiO₂ patterns were less effective than graphene patterns in dislocation reduction (FIG. 5E). The epilayer was only slightly relaxed near the edges of the SiO₂ mask (FIG. 5F) due to the rigidity and thickness of SiO₂, inducing localized strain. Therefore, these findings clarify that the deformable and slippery nature of graphene can provide an additional path for strain relaxation and allow for reduction of dislocations, whereas nucleation and threading of new dislocations were observed at the edges of the SiO₂ masks. It should be noted that effective elimination of APBs by the EPG technique has also been shown for lattice-mismatched heteroepitaxy system such as InGaAs on graphene-coated Ge substrates. In addition, heteroepitaxial films on the patterned graphene were successfully released from the substrates as in the case of GaAs and Ge material systems.

Air voids were occasionally formed during lateral overgrowth on graphene or SiO₂ masks, as shown in the cross-sectional STEM images in FIGS. 4A, 5B, and 5E. This phenomenon in epitaxial lateral overgrowth of III-V materials could be understood by one of ordinary skill in the art, and the formation of voids could be controlled or reduced by tuning the mask geometry or growth conditions. When laterally grown layers were merged, threading dislocations may be generated at the coalescence boundaries, which was also observed in the EPG approach described in this example. Although such threading dislocations initiated at coalescence boundaries adversely affected the overall crystal quality of epilayers, the overall crystal quality was improved by the EPG technique due to the roles of graphene described above.

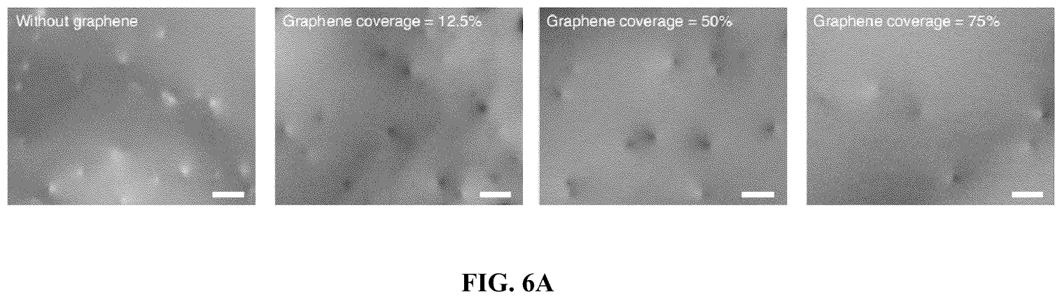

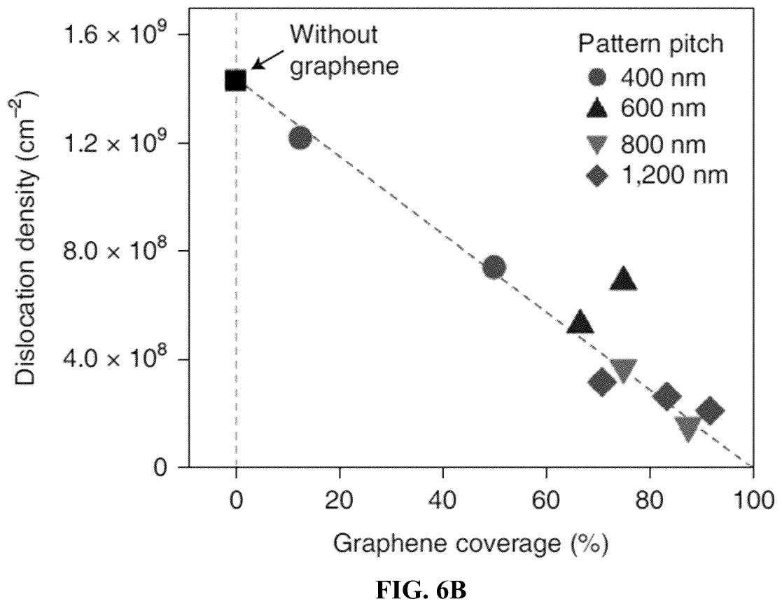

The impact of EPG technique on highly mismatched systems was studied by growing InAs on GaAs substrates, exhibiting 7.2% lattice-mismatch, with graphene patterns having various pitches and opening widths. As shown in the electron-channeling contrast images (ECCI) of InAs epilayers of the same thicknesses of 1 m (see FIG. 6A), dislocation density was progressively reduced on the surface as the graphene coverage increases. Monotonic decrease of dislocation density were observed by plotting the density as the function of the graphene coverage from 0% to 92%. This shows that the impact of graphene coverage was important as it shows an order of magnitude reduction of dislocations by simply varying the coverage (FIG. 6B). It should be highlighted that this technique provides unique solutions for obtaining heteroepitaxial films with significantly reduced dislocation densities that can be mechanically released from the substrate.

Exfoliation of the epitaxial material using the stressor layer was studied.

Three modes of peeling (spalling, exfoliation, and delamination) were denoted. In the spalling regime, the material is spalled not at the graphene interface, as shown in FIG. 3G. The spalling could occur at the substrate when the spalling depth is larger than the epilayer thickness, or at the epilayer if the spalling depth is smaller. In the exfoliation regime, the epilayer and the substrate are isolated at the graphene interface, which is the desired mode of peeling. In the delamination regime, the epilayer adheres to the substrate, while only the stressor layer or the handling tape is detached from the epilayer. The mode of peeling is determined by several factors, such as fracture toughness of materials, the thickness of epilayers and stressor layers, the stress level of stressor layers, and the graphene coverage (i.e., the area of graphene-covered region of the substrate divided by the entire surface area of the substrate). A model that can explain the three modes of peeling in the presence of a partially covered graphene interlayer was developed.

A Bulk Medium with a Stressor Layer.

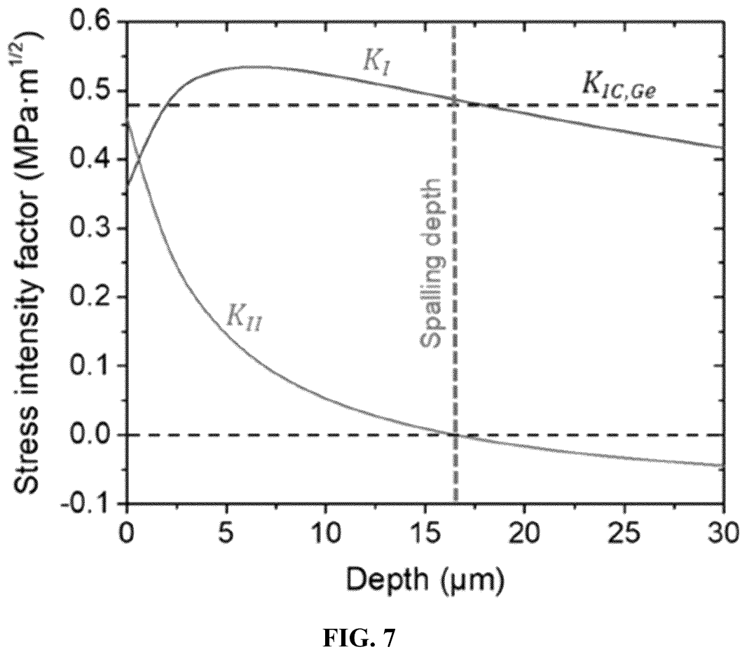

First, a simple case of a stressor layer on a bulk medium, without graphene, was considered. The model represents the case of spalling, by considering the stress intensity factors as a function of stressor/substrate thickness and elastic properties, as well as loading induced by the stressor at arbitrary crack depths. The resulting expressions for the two stress intensity factors, K_{I} and K_{II}, are described as:

$${K}_{I} = \frac{P}{\sqrt{2 Uh}} cos ( ω ) + \frac{M}{\sqrt{2 {Vh}^{3}}} sin ( ω + γ ) \qquad ( 1 )$$

$${K}_{II} = \frac{P}{\sqrt{2 Uh}} sin ( ω ) - \frac{M}{\sqrt{2 {Vh}^{3}}} cos ( ω + γ ) \qquad ( 2 )$$

where P is the edge load, M is the moment induced, U, V, and y are dimensionless constants derived from the elastic energy stored far behind the crack tip, h is the stressor thickness, and w is a dimensionless number representing the difference in elastic properties of the stressor and the substrate, as well as the crack depth. The values of these variables can be determined using the equations and methods described in the manuscript: Sui, Z. and Hutchinson, J. W., “Steady-State Cracking in Brittle Substrates Beneath Adherent Films,” Int. J. Solids Structures, Vol. 25, No. 11, pp. 1337-1353, 1989, which is incorporated herein by reference in its entirety for all purposes. As an example, consider a case that a 4-μm thick Ni stressor layer with the stress level of 600 Mpa, which is within a range from about 200 to 800 Mpa achievable by Ni sputtering, is deposited on 350-μm thick Ge(100) substrate. Eqns. 1 and 2 can be solved with the parameters of E_{Ni}=200 Gpa, v_{Ni}=0.31, h_{Ni}=4 μm, and σ_{Ni}=600 Mpa, E_{Ge}=103 Gpa, v_{Ge}=0.26, and t_{Ge}=350 μm, where E denotes Young's modulus. Calculation results are shown in FIG. 7. The spalling depth is determined at the depth where K_{II} becomes zero, as the crack propagates parallel to the stressor/substrate interface when K_{II}=0. To determine whether the crack propagates at all, K_{I} at this depth should be higher than the fracture toughness, K_{IC}, of the material, which is 0.48 Mpa-m¹¹² for Ge(100). Under the given conditions, spalling depth of Ge is determined as 16.5 μm as shown in FIG. 7. Such spalling occurs only when the stress level provided by the Ni stressor with a specific thickness is larger than K_{IC}. Otherwise, the stressor or the handling layer will simply delaminate from the epilayer, meaning that the thickness of a spalled layer has to be larger than a certain value. Because of the difficulty in precisely controlling the stressor deposition conditions and the spontaneous nature of spalling, it is challenging to accurately control the spalling depth in experiments, often showing discrepancies with theoretical estimation by more than several micrometers. Also, the spalling depth is typically nonuniform over the sample surface, with the fluctuations of several micrometers, making the controlled spalling-based approaches challenging for heterointegration.

### The Impact of Nanopatterned Graphene.

The introduction of graphene nanopatterns as an interlayer effectively weakens the interface due to the weak adhesion on van der Waals (vdW) surfaces of graphene, which offers a facile path for the propagation of cracks. For the crack to propagate at the interface, the atomic bonds at the interface need to be broken. Because the vdW bonding between the graphene and the bulk material (such as Ge or GaAs), which is formed on the region covered by graphene stripes, is several orders of magnitude weaker than the covalent bonding between the epilayer and the substrate, which is formed at the region uncovered by graphene, the contribution of graphene-covered region can be neglected for the calculation of energy release rate at the interface. At the front of a propagating crack, the portion of graphene-covered region is proportional to the graphene coverage regardless of the direction of peeling, and therefore, the effective fracture toughness, K_{IC,eff}, can be scaled from the fracture toughness of the bulk medium, K_{IC}, by the graphene coverage, x, as follows:

$${K}_{IC , eff} = ( 1 - x ) {K}_{IC} \qquad ( 3 )$$

Such reduction in fracture toughness with increasing graphene coverage results in a corresponding reduction in Ni stressor thickness required to peel the epilayer at the interface, as described in the following subsection.

### Determination of the Three Modes of Peeling.

The conditions for three modes of peeling with the presence of graphene interlayer are discussed below. The strain energy release rate, G, is related to the stress intensity factors by:

$$G = \frac{{c}_{2}}{8} ( {K}_{I}^{2} + {K}_{II}^{2} ) \qquad ( 4 )$$

where c₂ is a function of the Poisson's ratio. Therefore, even though K_{I} is solely responsible in conventional cases where crack propagates at the spalling depth (i.e., where K_{II} becomes zero), K_{II} can be non-zero in our case at the graphene interface, and thus both values should be considered to determine the mode of peeling. Therefore, the criteria can be set for spalling (in any direction) within the epilayer or substrate by the following equation:

$${K}_{I}^{2} + {K}_{II}^{2} \geq {K}_{IC}^{2} \qquad ( 5 )$$

Considering the case of Ge/graphene/Ge with a graphene coverage of 70%, then at σ_{Ni}=600 Mpa and t_{epilayer}=1 μm, the required Ni stressor thickness for crack propagation within the bulk material is h_{Ni}=2.91 m, which is derived from Eqns. 1, 2, and 5. Below this Ni stressor thickness, exfoliation at the graphene interface can occur if the K_{I} induced by the stressor, as calculated from Eqn. 1, is larger than K_{IC,eff}, as described by Eqn. 3. If not, the crack cannot propagate either within the bulk medium or the graphene interface, resulting in delamination of the stressor or the handling layer under the criterion:

$${K}_{I} \leq {K}_{IC , eff} \qquad ( 6 )$$

This occurs at h_{Ni}=0.30 μm, indicating that the range of Ni thickness for exfoliation of epilayer is 0.30-2.91 μm, as shown in FIGS. 3C and 3D.

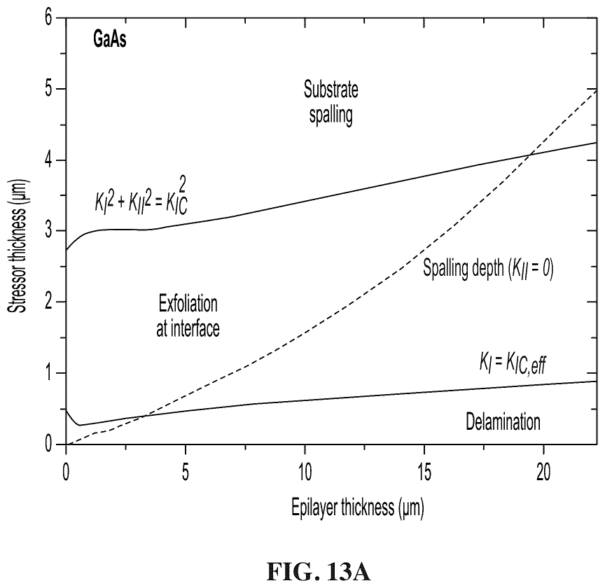

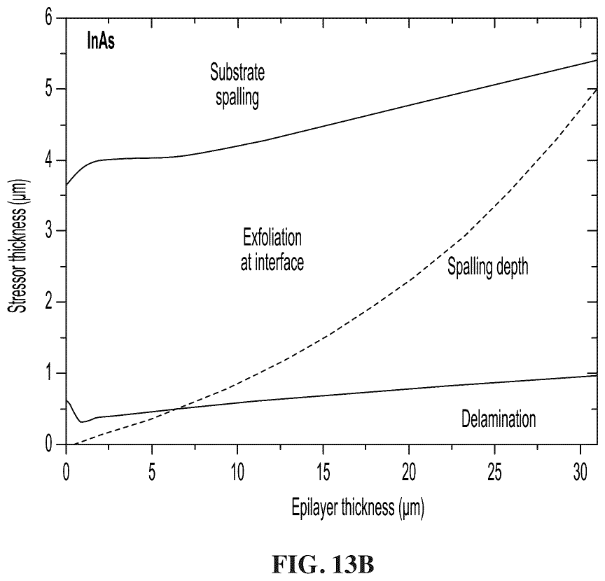

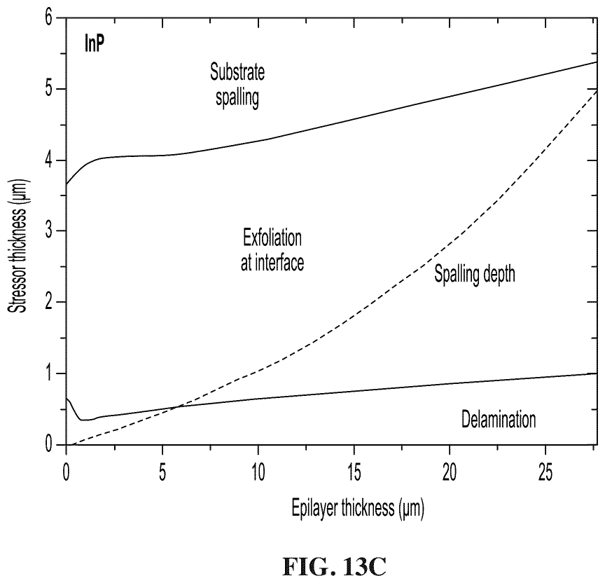

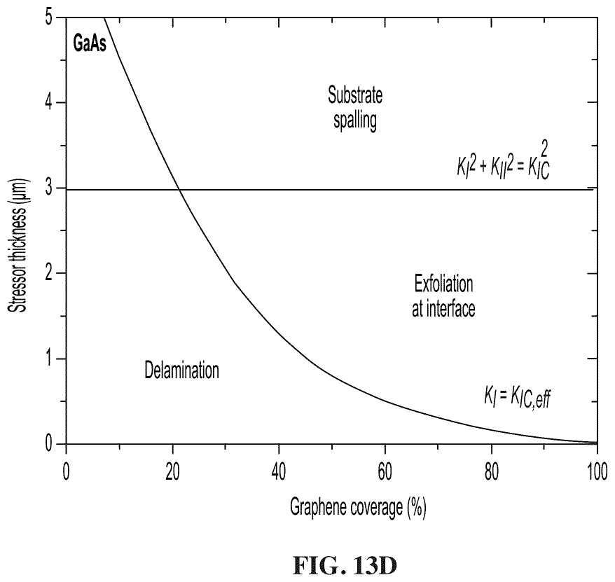

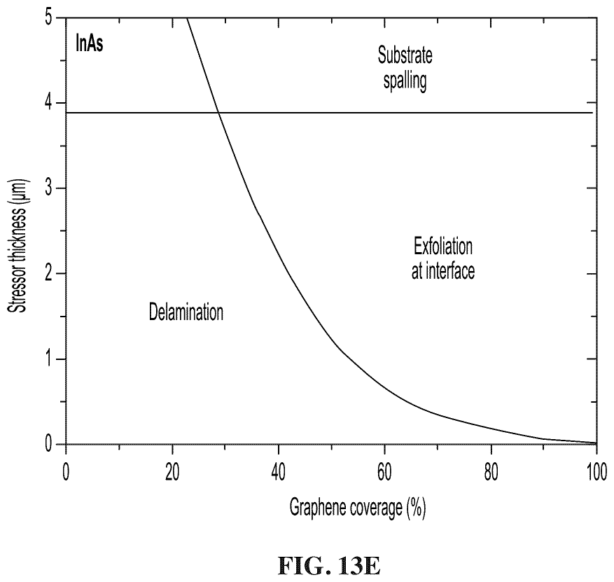

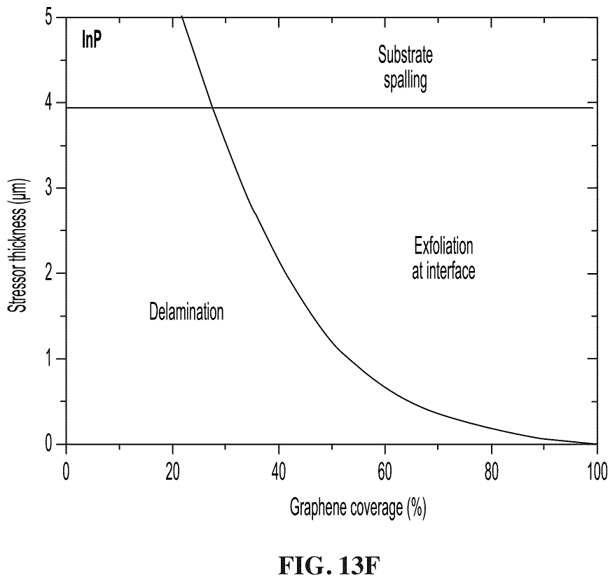

The required thickness of the Ni stressor layer for successful exfoliation varies by several factors. In general, when the graphene coverage, x, is large (such as >70%), there is a large window of the stressor thickness and stress level that allows for exfoliation. In other words, even if the stressor condition is not well-controlled, the epilayer will still be precisely exfoliated at the interface regardless of the thickness of the epilayer. On the other hand, when the graphene coverage becomes smaller, the stressor thickness required to satisfy Eqn. 3 becomes higher than that required to satisfy Eqn. 6 at some point, meaning that exfoliation cannot occur regardless of the stressor condition below a certain value of x. The same principles can be applied to any other material systems, such as GaAs/graphene/GaAs, GaAs/graphene/Ge, InAs/graphene/InAs, and InP/graphene/InP, with slight differences. First, in the heterostructure such as GaAs/graphene/Ge, the condition for spalling in the epilayer and in the substrate needs to be calculated separately, since GaAs and Ge have different K_{IC} values. Second, in the case of materials having {110} fracture planes, such as GaAs, the K_{IC} of the material along {110} planes needs to be used, not along {100}, and also, the increased surface area of a zig-zag crack needs to be considered. With those differences in mind, the peeling modes can be determined with the same principles, as described in FIG. 13A-F. Different upper/lower threshold Ni thicknesses for each material system depending on the intrinsic material properties (e.g., E_{GaAs}=85 Gpa, v_{GaAs}=0.32, and K_{IC,GaAs}=0.44 Mpa·m^{1/2} for GaAs, E_{InAs}=51.4 Gpa, v_{InAs}=0.35, and K_{IC,InAs}=0.38 Mpa·m^{1/2} for InAs, and E_{InP}=61.1 Gpa, v_{InP}=0.36, and K_{IC,InP}=0.42 Mpa·m^{1/2} for InP). GaAs shows a similar peeling window with Ge in terms of the stressor thickness, while InAs and InP exhibit wider exfoliation regimes than Ge. On the other hand, the minimum graphene coverage allowing for the film exfoliation is smaller for GaAs and Ge than for InAs and InP.

A broad choice of stressor metals and their stress levels for the design of efficient and functional devices with flexibility in their fabrication processes could be advantageous. Gold and silver can be employed as a stressor layer for peeling based on conventional spalling approaches. Therefore, the gold layer, for example, could be directly utilized as a back reflector of optoelectronic devices after being used as a stressor layer. In addition, a much higher stress level in Ni (over 1000 Mpa) can be achieved by electroplating of Ni instead of sputtering. Higher stress allows for harvesting thinner membranes by conventional mechanical spalling. However, such a high stress level is not required in the approach described in this disclosure because epilayers of any thickness can be exfoliated when the nanopatterned graphene interlayer is introduced, and the peelable window of Ni thickness rather shrinks under high-stress stressors, as illustrated in FIG. 11A. Nevertheless, the minimum graphene coverage allowing for the exfoliation becomes smaller under higher stress level which could be beneficial in certain cases with small graphene coverage.

The explanation provided here is, to a certain extent, simplified in that the interfacial fracture toughness is scaled as K_{IC,eff}, whereas in reality, the interface is composed of two regions with K_{IC}=K_{IC,bulk} and K_{IC}=K_{IC,graphene}≈0, for exposed and graphene-covered regions, respectively. Such simplification could induce differences between the theoretically derived peeling mode and experimental results under specific conditions. For example, under the condition of σ_{Ni}=600 Mpa and t_{epilayer}=1 μm, exfoliation is possible when x is larger than about 0.2. Experimentally, exfoliation was not successful below x of about 0.4. Also, at a higher graphene coverage (about 0.5), partial failure of exfoliation (i.e., local spalling) was observed, because K_{II} is non-zero at the interface and the propagation of crack at the exposed region of the interface along out-of-plane direction has a chance for such local spalling.

Analytical solutions from conventional spalling theory to estimate the criteria for exfoliation at graphene interfaces were developed. In principle, the generation and propagation of cracks through a medium are governed by stress intensity factors, K_{I}(opening mode) and K_{II} (shear mode), exerted by the stressor layer, and fracture toughness K_{IC} of the spalled medium. When graphene nanopatterns are introduced, the presence of graphene effectively weakens the interface because the bonding strength of graphene-covered surface is marginal. For a graphene coverage percentage of x, the effective fracture toughness at the interface becomes,

K_{IC,eff}=(1−x)K_{IC},

and, as the thickness of the epilayer deviates from the spalling depth (K_{II}≠0), the condition for spalling changes to,

K_{I}²+K_{II}²>K_{IC}².

On the other hand, the delamination of a stressor layer from the surface of the epilayer occurs when the energy release rate provided by the stressor is not sufficient for crack propagation, expressed as,

K_{I}<K_{IC,eff},

and outside these spalling and delamination regimes, exfoliation occurs at the graphene interface.

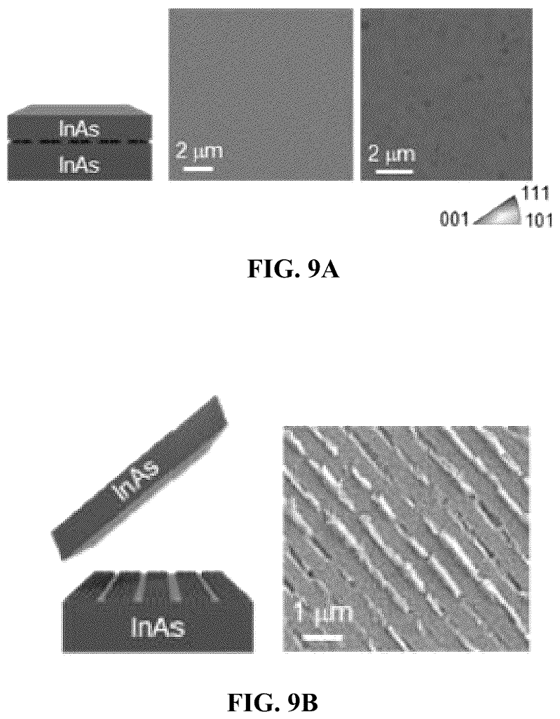

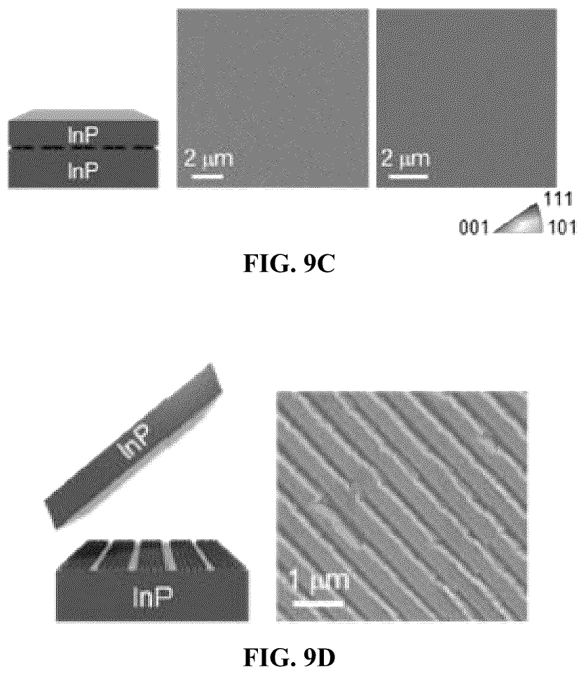

The developed exfoliation criteria (FIG. 3C and FIG. 3D) agreed well with the experimental results. As shown in the photograph and SEM images in FIG. 3E and FIG. 3F, the entire area of the 1 μm-thick epilayer could be exfoliated off of the wafer, determined by the plots in FIGS. 3C and 3D. The surface morphology of the substrate following exfoliation was flat on the graphene-covered regions, while exposed regions show undulations with a height fluctuation of tens of nanometers (FIG. 3F). When the accumulated strain energy within the Ni stressor layer was high (K_{I}²+K_{II}²>K_{IC}²), the substrate spalls and reveals its zig-zag {110} cleavage planes of GaAs and a relatively planar (100) plane for Ge, as shown in FIG. 3G. On the other hand, when the stress was too low (K_{I}<K_{IC,eff}), then cracks could not propagate, resulting in the delamination of the Ni layer or the handling tape, as shown in FIG. 3H. The same principle could be applied to produce freestanding membranes for different materials as well (FIG. 9A-D). This is in contrast to the conventional controlled spalling method, wherein the spalling depth cannot be reliably controlled and the spalled surface is roughened.

Graphene nanopatterns were demonstrated as a platform for the epitaxy of single-crystal films, where both elemental and compound semiconductors can be used for the substrates as well as the epilayers. Three modes of peeling—spalling, exfoliation, and delamination—were theoretically proposed and experimentally demonstrated, showing that the grown films could be readily exfoliated with good controllability regardless of the film thickness due to the weak interfaces intentionally formed by graphene stripes. Moreover, APBs completely disappeared when III-V films were grown on elemental substrates with graphene stripes, resulting in high-quality optoelectronics III-V devices that can be made freestanding and transferred onto foreign platforms for heterointegration. Theoretical analysis of dislocation reduction by the dangling-bond-free and ultrathin graphene in lattice-mismatched heteroepitaxy supports the experimental results. Overall, a new pathway was provided for the production of various high-quality and single-crystal membranes, overcoming polarity and lattice-matching constraints which have been a critical obstacle for heterointegrated multifunctional systems.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, and/or method described herein. In addition, any combination of two or more such features, systems, articles, materials, and/or methods, if such features, systems, articles, materials, and/or methods are not mutually inconsistent, is included within the scope of the present invention.

The indefinite articles “a” and “an,” as used herein in the specification and in the claims, unless clearly indicated to the contrary, should be understood to mean “at least one.”

The phrase “and/or,” as used herein in the specification and in the claims, should be understood to mean “either or both” of the elements so conjoined, i.e., elements that are conjunctively present in some cases and disjunctively present in other cases. Other elements may optionally be present other than the elements specifically identified by the “and/or” clause, whether related or unrelated to those elements specifically identified unless clearly indicated to the contrary. Thus, as a non-limiting example, a reference to “A and/or B,” when used in conjunction with open-ended language such as “comprising” can refer, in one embodiment, to A without B (optionally including elements other than B); in another embodiment, to B without A (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

1. A method of growing an epitaxial layer, comprising:
growing an epitaxial layer over a structure comprising a crystalline substrate and a mask such that the mask is between the epitaxial layer and the crystalline substrate; and
separating the epitaxial layer and the crystalline substrate from each other;
wherein:
the crystalline substrate has a diamond cubic crystal structure or a zinc blende crystal structure;
the mask and the epitaxial layer are over a {100} plane of the crystalline substrate;
the mask comprises a plurality of elongated domains, each elongated domain having long edges;
each of the long edges is within 100 of parallel to a <110> direction on the {100} plane of the crystalline substrate, on a {100} plane of the epitaxial layer, or both.

2. A method of growing an epitaxial layer, comprising:
growing an epitaxial layer over a structure comprising a crystalline substrate and a mask comprising a plurality of elongated domains, each elongated domain having long edges, such that elongated domains are between the epitaxial layer and the crystalline substrate; and
separating the epitaxial layer and the crystalline substrate from each other;
wherein:
the elongated domains of the mask are not connected to each other; and
the elongated domains occupy at least 50% of a facial surface area of the crystalline substrate.

3. The method of claim 2, wherein the crystalline substrate comprises a diamond cubic crystal structure.

4. The method of claim 2, wherein the epitaxial layer comprises a diamond cubic crystal structure.

5. The method of claim 2, wherein the crystalline substrate comprises a zinc blende crystal structure.

6. The method of claim 2, wherein the epitaxial layer comprises a zinc blende crystal structure.

7. The method of claim 2, wherein a polarity of the crystalline substrate is different than a polarity of the epitaxial layer.

8. The method of claim 2, wherein the mask comprises a 2D material.

9. The method of claim 2, wherein the epitaxial layer comprises a threading dislocation density of less than or equal to 10⁷ threading dislocations per cm².

10. The method of claim 2, wherein the epitaxial layer comprises a surface anti-phase domain density of less than or equal to 10⁶ anti-phase domains per cm².

11. The method of claim 2, wherein each of the plurality of elongated domains has an aspect ratio of at least 10:1.

12. The method of claim 2, wherein an average nearest neighbor distance among the plurality of elongated domains is less than or equal to 10 micrometers.

13. The method of claim 2, wherein the crystalline substrate comprises silicon.

14. The method of claim 2, wherein the epitaxial layer comprises silicon.

15. The method of claim 2, wherein the crystalline substrate comprises germanium.

16. The method of claim 2, wherein the epitaxial layer comprises germanium.

17. The method of claim 2, wherein the crystalline substrate comprises a compound semiconductor.

18. The method of claim 2, wherein the epitaxial layer comprises a compound semiconductor.

19. The method of claim 2, wherein the plurality of elongated domains cover at least 50% of the facial surface area of the crystalline substrate over which the epitaxial layer is grown

20. The method of claim 2, wherein separating the epitaxial layer comprises exfoliating the epitaxial layer from the crystalline substrate.

21. The method of claim 2, wherein the epitaxial layer is a first epitaxial layer, and further comprising growing a second epitaxial layer over the structure after separating the first epitaxial layer and the crystalline substrate from each other.

22. The method of claim 2, wherein each of the long edges is within 10° of parallel to a <110> direction on the {100} plane of the crystalline substrate.

23. The method of claim 2, wherein each of the long edges is within 1 degree of parallel to a <110> direction on the {100} plane of the crystalline substrate.

24. The method of claim 2, wherein the epitaxial layer has a facial surface area of at least 10 square micrometers.

25. A method of growing an epitaxial layer, comprising:
growing an epitaxial layer over a structure comprising a crystalline substrate and a mask such that the mask is between the epitaxial layer and the crystalline substrate;
wherein a lattice mismatch between the crystalline substrate and the epitaxial layer is at least 1% and less than or equal to 80%; and
wherein:
the epitaxial layer comprises a threading dislocation density of less than or equal to 10⁹ threading dislocations per cm²; and/or
the epitaxial layer comprises a surface anti-phase domain density of less than or equal to 10⁷ anti-phase domains per cm².

26. The method of claim 25, wherein the epitaxial layer comprises a threading dislocation density of less than or equal to 10 threading dislocations per cm².

27. The method of claim 25, wherein the epitaxial layer comprises a surface anti-phase domain density of less than or equal to 10 anti-phase domains per cm².
